(19) United States
(12) Patent Application Publication
(10) Pub. No.: US 2025/0331230 A1
(43) Pub. Date: Oct. 23, 2025

(54) Source/Drain Structure with Bottom Insulation

(71) Applicant: Taiwan Semiconductor Manufacturing Company, Ltd., Hsin-Chu (TW)

(72) Inventors: Shi-Sheng HU, Tainan City (TW); Szu-Chi YANG, Hsinchu City (TW); Ming-Lung CHENG, Kaohsiung County (TW)

(21) Appl. No.: 18/827,179

(22) Filed: Sep. 6, 2024

Related U.S. Application Data
(60) Provisional application No. 63/635,943, filed on Apr. 18, 2024.

(51) Int. Cl. H01L 29/417; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121

(57) ABSTRACT

Source/drain structures having bottom insulation and methods of fabrication thereof are disclosed herein. An exemplary source/drain structure includes a base semiconductor layer having a first composition, an insulator layer, a first semiconductor layer having a second composition, and a second semiconductor layer having a third composition. The base semiconductor layer is disposed in a substrate. The insulator layer is disposed on the base semiconductor layer, and the insulator layer includes at least one break therein that exposes a portion of the base semiconductor layer. The first semiconductor layer is disposed on a channel layer (which may extend from or be suspended over the substrate). The first semiconductor layer is also disposed on the exposed portion of the base semiconductor layer. The second semiconductor layer is disposed on the insulator layer and the first semiconductor layer. The third composition, the second composition, and the first composition are different.

This application is a non-provisional application of and claims benefit of U.S. Provisional Patent Application Ser. No. 63/635,943, filed Apr. 18, 2024, the entire disclosure of which is incorporated herein by reference.

### BACKGROUND

Recently, multigate devices, which have gates that extend, partially or fully, around a channel to provide access to the channel on at least two sides, have been introduced to improve gate control. Exemplary multigate devices include fin-like field effect transistors (FinFETs) and gate-all around (GAA) transistors, such as nanowire transistors. Multigate devices enable aggressive scaling down of integrated circuit (IC) technologies, maintaining gate control, and mitigating short-channel effects (SCEs), while seamlessly integrating with related IC manufacturing processes. However, as multigate devices continue to scale with scaling IC nodes, epitaxial source/drain structures are needed for facilitating smaller feature sizes and denser packing of features in advanced IC technology nodes. Accordingly, although existing epitaxial source/drain structures and methods for fabricating such have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method, in portion or entirety, for fabricating an improved source/drain structure according to various aspects of the present disclosure.

FIGS. 2A-2K are cross-sectional views of a device, in portion or entirety, at various fabrication stages, such as those associated with the method in FIG. 1 for fabricating the improved source/drain structure, according to various aspects of the present disclosure.

FIGS. 3A-3K are perspective views of the device, in portion or entirety, at various fabrication stages, such as those associated with the method in FIG. 1 for fabricating the improved source/drain structure, according to various aspects of the present disclosure.

FIGS. 4A-4F are cross-sectional views of another device, in portion or entirety, at various fabrication stages, such as those associated with the method in FIG. 1 for fabricating the improved source/drain structure, according to various aspects of the present disclosure.

FIG. 5 is a cross-sectional view of yet another device, in portion or entirety, that may implement the method in FIG. 1 for fabricating different configurations of improved source/drain structure according to various aspects of the present disclosure.

FIG. 6A and FIG. 6B are cross-sectional views of yet another device, in portion or entirety, that may implement the method in FIG. 1 for fabricating different configurations of the improved source/drain structure according to various aspects of the present disclosure.

FIG. 7 is a top view of yet another device, in portion or entirety, that may implement the method in FIG. 1 for fabricating different configurations of the improved source/drain structure according to various aspects of the present disclosure.

### DETAILED DESCRIPTION

The present disclosure relates generally to epitaxial source/drain structures for enhancing performance of multigate devices, such as fin-like field-effect transistors (FETs) and/or gate-all-around (GAA) FETs, and methods of fabrication thereof.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure provides source/drain structures with bottom insulation that are configured to optimize performance of a multigate device, such as a GAA transistor. The disclosed source/drain structures are configured with breaks within the bottom insulation, which may improve growth and/or optimize strain of source/drain material. The disclosed source/drain structures may thus improve AC gain (e.g., by incorporating bottom insulation) without strain loss (e.g., by incorporating breaks within the bottom insulation). Different embodiments may have different advantages, and no particular advantage is required of any embodiment.

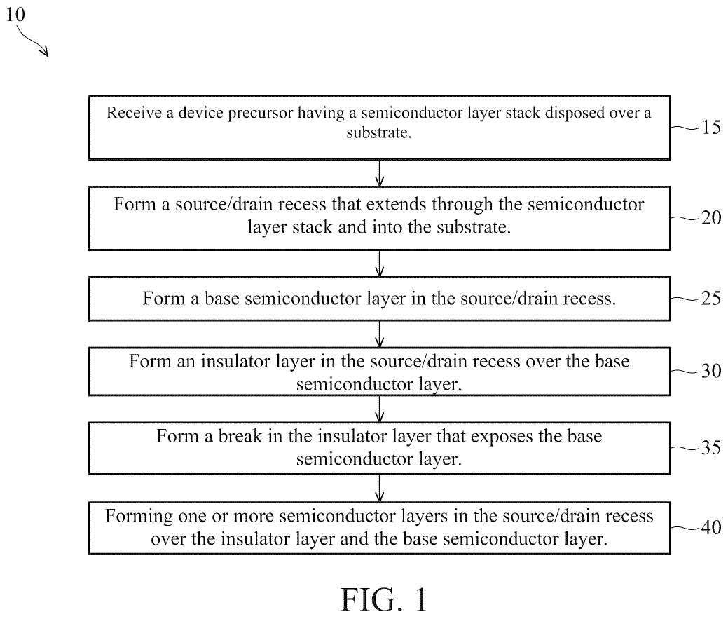

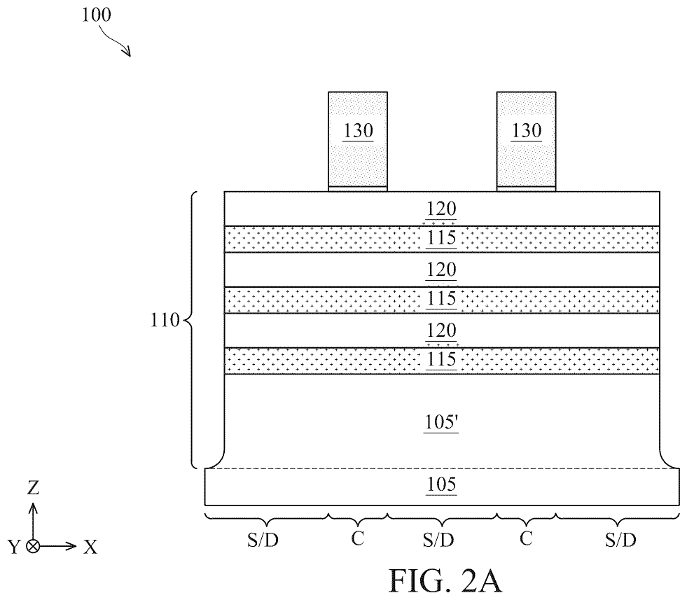

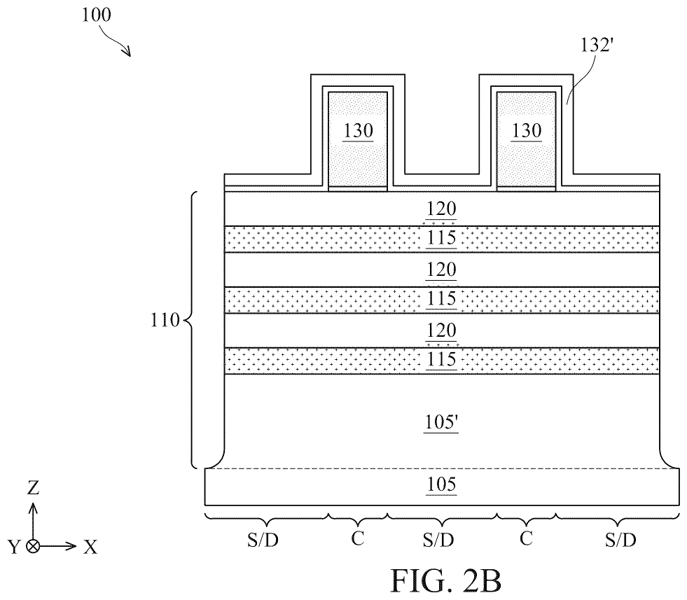

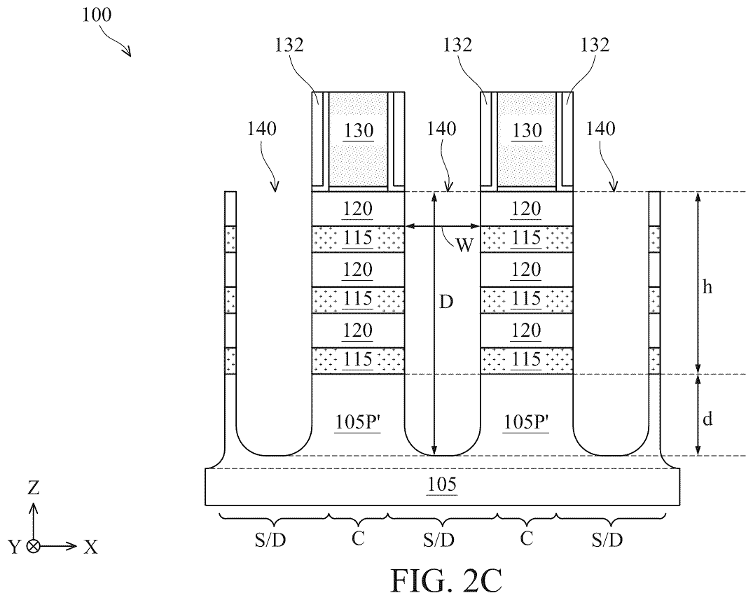

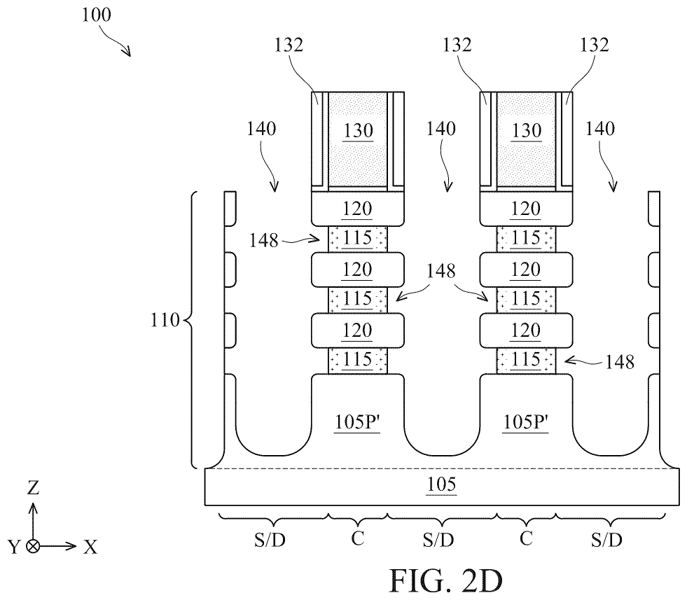

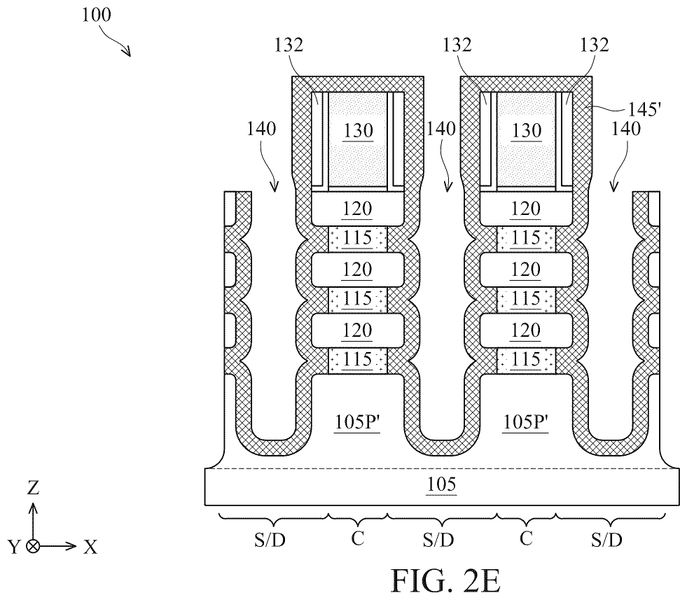

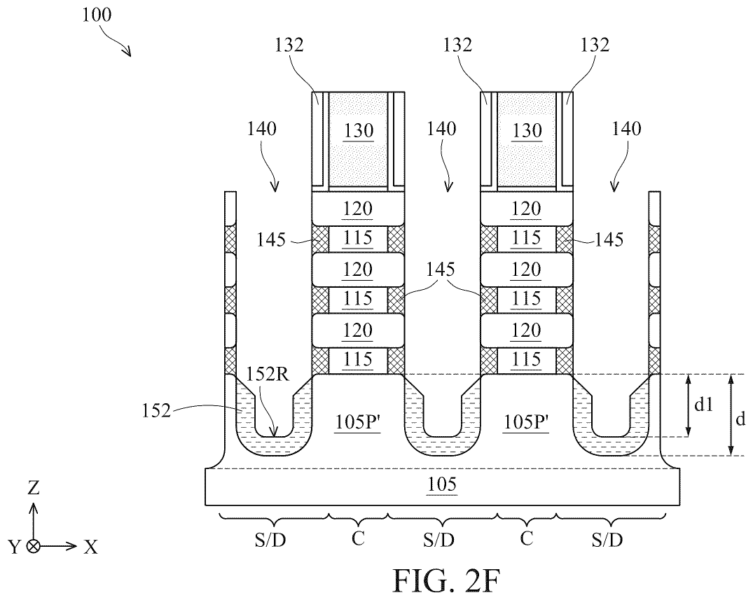

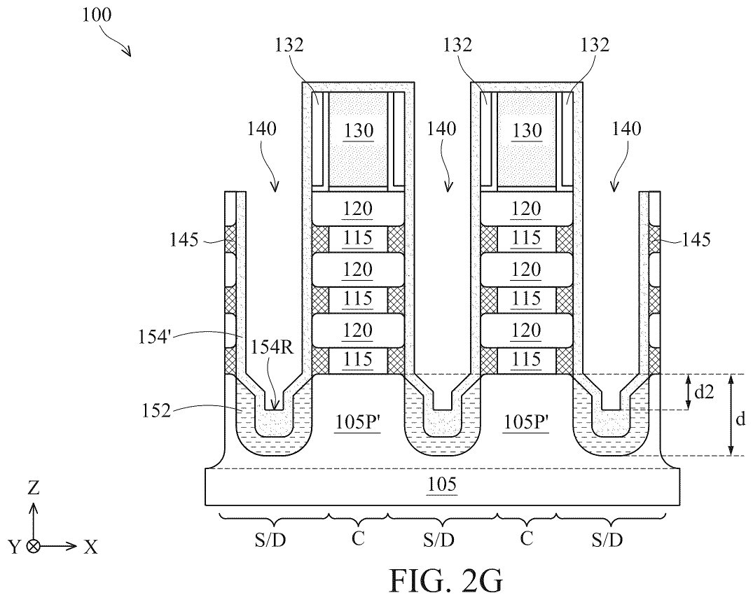

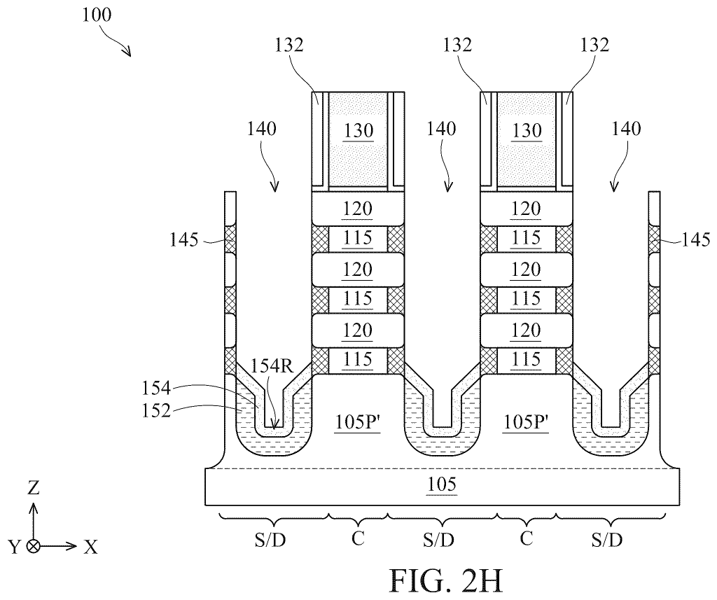

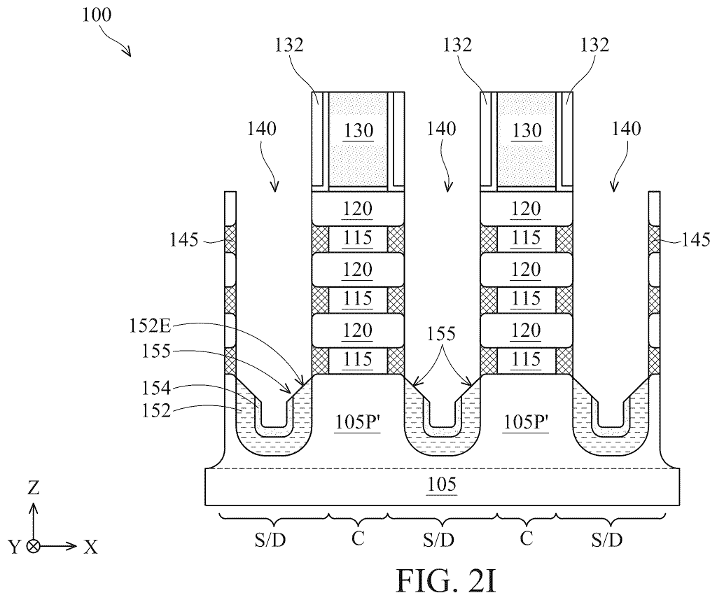

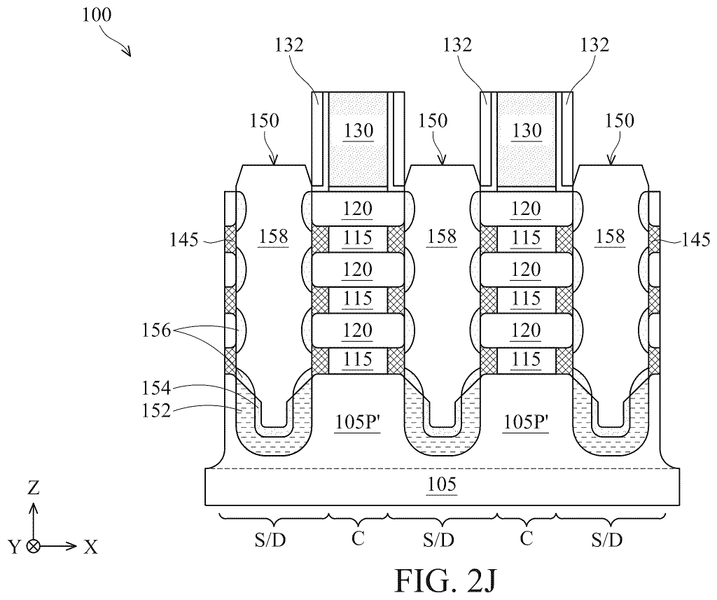

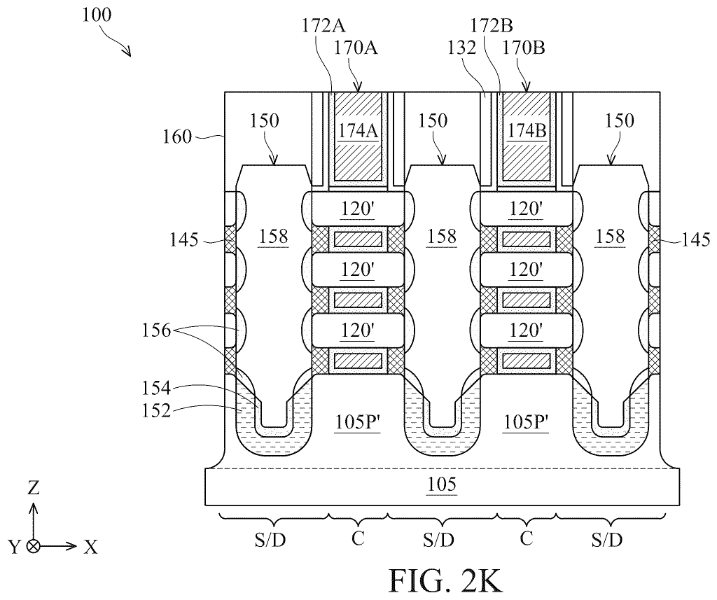

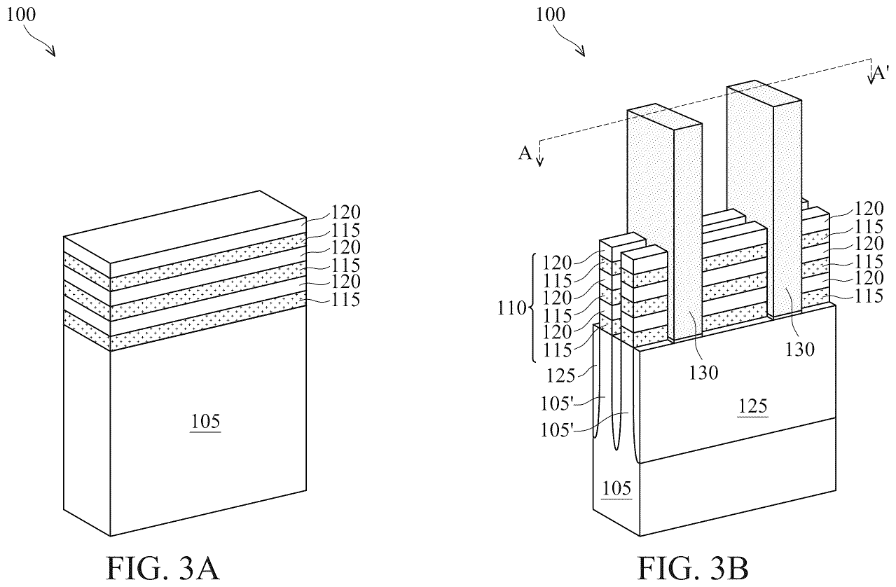

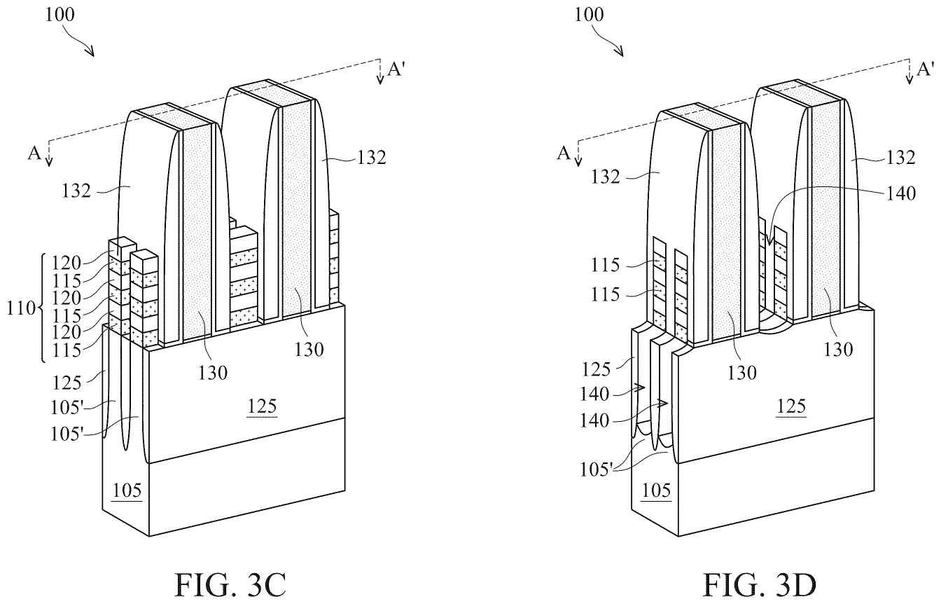

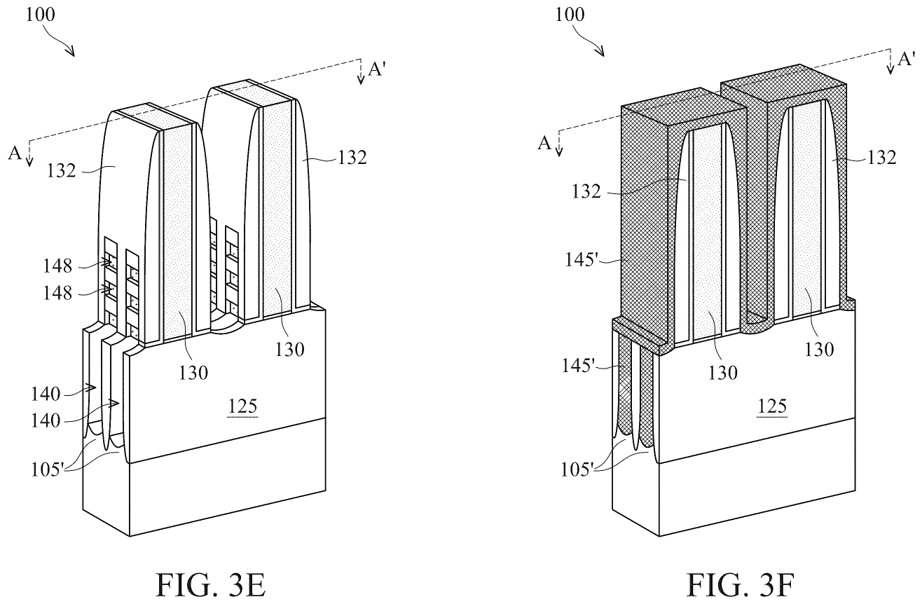

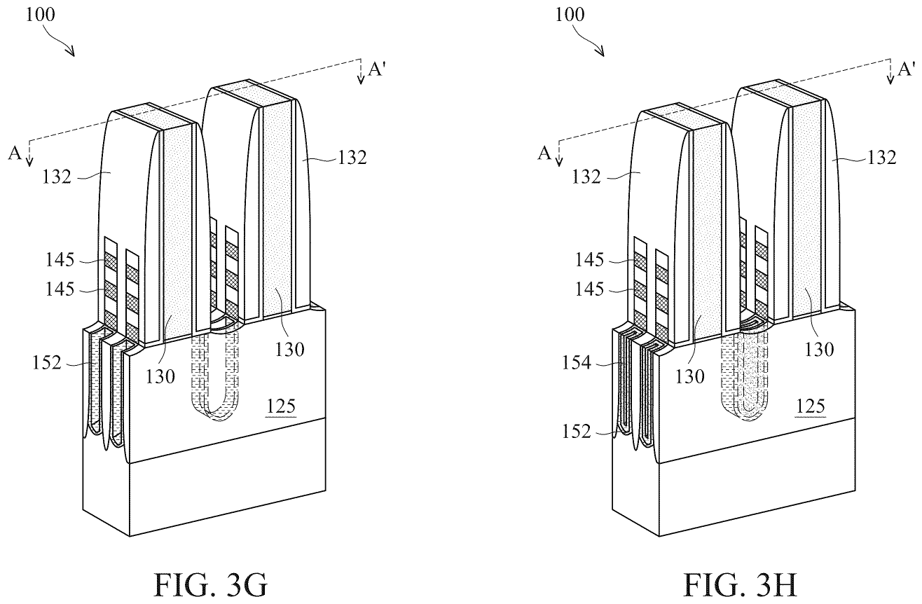

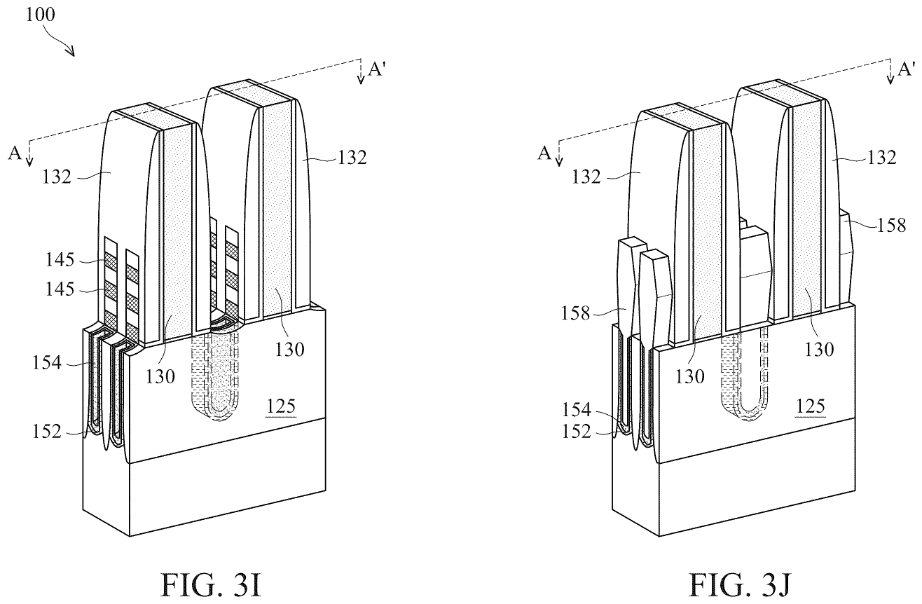

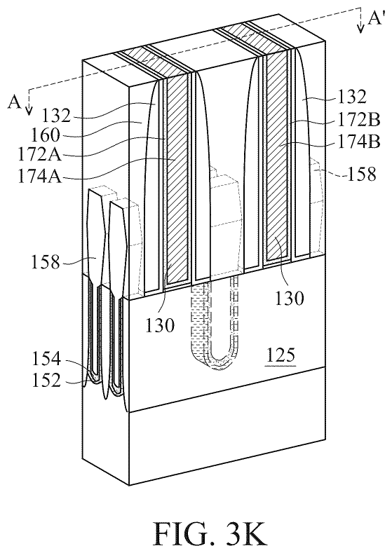

FIG. 1 is a flow chart of a method 10, in portion or entirety, for fabricating a source/drain structure according to various aspects of the present disclosure. FIGS. 2A-2K are cross-sectional views of a device 100, in portion or entirety, at various fabrication stages associated with method 10 in FIG. 1 according to various aspects of the present disclosure. FIGS. 3A-3K are perspective views of device 100, in portion or entirety, at various fabrication stages associated with method 10 in FIG. 1 according to various aspects of the present disclosure. FIG. 3A and FIG. 3B correspond with the fabrication stage at FIG. 2A (which is taken along line A-A′ of FIG. 3B), FIG. 3C and FIG. 3D correspond with the fabrication stage at FIG. 2C (which is taken along line A-A′ of FIG. 3D), FIG. 3E corresponds with the fabrication stage at FIG. 2C (which is taken along line A-A′ of FIG. 3D), FIG. 3E corresponds with the fabrication stage at FIG. 2D (which is taken along line A-A′ of FIG. 3E), FIG. 3F corresponds with the fabrication stage at FIG. 2E (which is taken along line A-A′ of FIG. 3F), FIG. 3G corresponds with the fabrication stage at FIG. 2F (which is taken along line A-A′ of FIG. 3G), FIG. 3H corresponds with the fabrication stage at FIG. 2H (which is taken along line A-A′ of FIG. 3H), FIG. 3I corresponds with the fabrication stage at FIG. 2I (which is taken along line A-A′ of FIG. 3I), FIG. 3J corresponds with the fabrication stage at FIG. 2J (which is taken along line A-A′ of FIG. 3J), and FIG. 3K corresponds with the fabrication stage at FIG. 2K (which is taken along line A-A′ of FIG. 3K). FIG. 1, FIGS. 2A-2K, and FIGS. 3A-3K are discussed concurrently herein for ease of description and understanding. FIG. 1, FIGS. 2A-2K, and FIGS. 3A-3K have been simplified for the sake of clarity to better understand the inventive concepts of the present disclosure. Additional steps can be provided before, during, and after method 10, and some of the steps described can be moved, replaced, or eliminated for additional embodiments of method 10. Additional features can be added in device 100, and some of the features described below can be replaced, modified, or eliminated in other embodiments of device 100.

Device 100 may include at least one GAA transistor (i.e., a transistor having a gate that at least partially surrounds a suspended channel(s) (for example, nanowires, nanosheets, nanobars, or the like) that extends between source/drains). In some embodiments, device 100 includes p-type GAA transistors and/or n-type GAA transistors. Device 100 may be included in a microprocessor, a memory, other IC device, or combinations thereof. In some embodiments, device 100 is a portion of an IC chip, a system on chip (SoC), or portion thereof, that includes various passive electronic devices and/or active electronic devices, such as resistors, capacitors, inductors, diodes, p-type field effect transistors (PFETs), n-type FETs (NFETs), metal-oxide-semiconductor FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof.

Referring to FIG. 1 and FIG. 2A (and corresponding FIG. 3A and FIG. 3B), method 10 at block 15 includes receiving and/or forming a device precursor, which may be processed to form source/drains of device 100. As used herein, source/drain, source/drain region, source/drain structure, epitaxial source/drain, epitaxial source/drain feature, etc. may refer to a source of device 100, a drain of device 100, or a source and/or a drain of multiple devices (including device 100). In FIG. 2A, device 100 has undergone processing associated with FIG. 3A and FIG. 3B, and the device precursor includes a substrate 105 and a semiconductor layer stack 110, which may include semiconductor layers 115, semiconductor layers 120, and a mesa 105′ (e.g., a patterned, projecting portion of substrate 105). The device precursor may also include substrate isolation structures 125 and dummy gates 130.

Substrate 105 includes an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GalnAs, GalnP, GalnAsP, or combinations thereof; or combinations thereof. In some embodiments, substrate 105 is a silicon substrate. In some embodiments, substrate 105 is a semiconductor-on-insulator substrate, such as a silicon-on-insulator (SOI) substrate, a silicon germanium-on-insulator (SGOI) substrate, or a germanium-on-insulator (GOI) substrate. Substrate 105 (and mesa 105′) may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, gallium, other p-type dopant, or combinations thereof. In some embodiments, the doped regions include combinations of p-type dopants and n-type dopants. The doped regions may be formed directly on and/or in substrate 105, for example, providing a p-well structure, an n-well structure, a dual-well structure, a raised structure, other suitable structure, or combinations thereof. In some embodiments, substrate 105 and/or mesa 105′, and semiconductor layers thereover, may include an n-well and/or a p-well.

In some embodiments, semiconductor layer stack 110 is formed by depositing semiconductor layers 115 and semiconductor layers 120 over substrate 105 (e.g., FIG. 3A) and patterning semiconductor layers 115, semiconductor layers 120, and substrate 105 to form semiconductor layer stack 110 extending from substrate 105 (e.g., FIG. 3B). In FIG. 3A, semiconductor layers 115 and semiconductor layers 120 are stacked vertically (e.g., along the z-direction) in an interleaving and/or alternating configuration from the top of substrate 105. In some embodiments, the depositing includes epitaxially growing semiconductor layers 115 and semiconductor layers 120 in the depicted interleaving/alternating configuration. For example, a first one of semiconductor layers 115 is epitaxially grown on substrate 105, a first one of semiconductor layers 120 is epitaxially grown on the first one of semiconductor layers 115, a second one of semiconductor layers 115 is epitaxially grown on the first one of semiconductor layers 120, and so on until semiconductor layer stack 110 has a desired number of semiconductor layers 115 and semiconductor layers 120. In such embodiments, semiconductor layers 115 and semiconductor layers 120 may be referred to as epitaxial layers. In some embodiments, epitaxial growth of semiconductor layers 115 and semiconductor layers 120 is achieved by a molecular beam epitaxy (MBE) process, a chemical vapor deposition (CVD) process, a metalorganic (MOCVD) process, other suitable epitaxial growth process, or combinations thereof.

A composition of semiconductor layers 115 is different than a composition of semiconductor layers 120 to achieve different etching selectivity and/or different oxidation rates during subsequent processing. For example, semiconductor layers 115 and semiconductor layers 120 include different materials, constituent atomic percentages, constituent weight percentages, thicknesses, and/or other characteristics to achieve etching selectivity during an etching process, such as an etching process implemented to form suspended channel layers in channel regions. In some embodiments, semiconductor layers 115 include silicon germanium, semiconductor layers 120 include silicon, and a silicon etch rate of semiconductor layers 120 is different than a silicon germanium etch rate of semiconductor layers 115 to a given etchant. In some embodiments, semiconductor layers 115 and semiconductor layers 120 include the same material but with different constituent atomic percentages to achieve the etching selectivity and/or different oxidation rates. For example, semiconductor layers 115 and semiconductor layers 120 may include silicon germanium, where semiconductor layers 115 and semiconductor layers 120 have different silicon atomic percentages and/or different germanium atomic percentages. Semiconductor layers 115 and semiconductor layers 120 may include any combination of semiconductor materials that provides desired etching selectivity, desired oxidation rate differences, and/or desired performance characteristics (e.g., materials that maximize current flow), including any of the semiconductor materials disclosed herein.

Referring to FIG. 2A and FIG. 3B, after patterning, semiconductor layer stack 110 includes mesa 105′ (also referred to as a substrate extension, a substrate fin portion, a fin portion, an etched substrate portion, etc.) and a semiconductor layer stack portion (i.e., semiconductor layers 115 and semiconductor layers 120). Semiconductor layer stack 110 extends substantially along the x-direction, having a length along the x-direction, a width along a y-direction, and a height along a z-direction. Semiconductor layer stacks 110 may extend substantially parallel to one another. In some embodiments, a lithography process and/or an etching process is performed to pattern semiconductor layers 115, semiconductor layers 120, and substrate 105 to form semiconductor layer stack 110. In some embodiments, semiconductor layer stack 110 is formed by a multiple patterning process, such as a double patterning lithography (DPL) process (for example, a lithography-etch-lithography-etch (LELE) process, a self-aligned double patterning (SADP) process, a spacer-is-dielectric (SID) process, other double patterning process, or combinations thereof), a triple patterning process (for example, a lithography-etch-lithography-etch-lithography-etch (LELELE) process, a self-aligned triple patterning (SATP) process, other triple patterning process, or combinations thereof), other multiple patterning process (for example, self-aligned quadruple patterning (SAQP) process), or combinations thereof. In some embodiments, directed self-assembly (DSA) techniques are implemented while forming semiconductor layer stack 110. In some embodiments, semiconductor layer stack 110 is formed by a fin fabrication process and semiconductor layer stack 110 can be referred to as a fin, a fin structure, a fin element, an active fin region, an active region, etc.

After patterning, substrate isolation structures 125 may be formed in trenches around semiconductor layer stack 110, and semiconductor layer stack 110 may be separated from other semiconductor layer stacks 110 by substrate isolation structures 125. In some embodiments (e.g., FIG. 3B), substrate isolation structures 125 may be formed by depositing an insulator material (e.g., by a CVD process or a spin-on glass process) over substrate 105 that fills, partially or entirely, the trenches and performing a chemical mechanical polishing (CMP) process to remove excess insulator material and/or planarize top surfaces of substrate isolation structures 125. The deposition process may be a flowable CVD (FCVD) process, a high aspect ratio deposition (HARP) process, a high-density plasma CVD (HDPCVD) process, other suitable deposition process, or combinations thereof. In some embodiments, the CMP process removes insulator material over a top of semiconductor layer stack 110. In some embodiments, the insulator material is etched back, such that semiconductor layer stack 110 extends a distance beyond the top of substrate isolation structures 125 (i.e., a top surface of semiconductor layer stack 110 is higher than top surfaces of substrate isolation structures 125).

Substrate isolation structures 125 may electrically isolate an active device region (e.g., semiconductor layer stack 110) from other device regions (e.g., another active device region, such as another semiconductor layer stack 110 and/or a passive device region). Substrate isolation structures 125 include silicon oxide, silicon nitride, silicon oxynitride, other suitable isolation material (including, silicon, oxygen, nitrogen, carbon, other suitable isolation constituent, or combinations thereof), or combinations thereof. Substrate isolation structures 125 may have a multilayer structure. For example, substrate isolation structures 125 may include a bulk dielectric (e.g., an oxide layer) over a dielectric liner (e.g., silicon nitride, silicon oxide, silicon oxynitride, silicon oxycarbonitride, or combinations thereof). In another example, substrate isolation structures 125 may include a bulk dielectric over a doped liner, such as a boron silicate glass (BSG) liner and/or a phosphosilicate glass (PSG) liner. Dimensions and/or characteristics of substrate isolation structures 125 are configured to provide shallow trench isolation (STI) structures, deep trench isolation (DTI) structures, local oxidation of silicon (LOCOS) structures, other suitable isolation structures, or combinations thereof.

As depicted in FIG. 2A and FIG. 3B, dummy gates 130 are formed over channel regions (C) of semiconductor layer stack 110 and between respective source/drain regions (S/D) of semiconductor layer stack 110. Dummy gates 130 extend lengthwise in a direction that is different than (e.g., orthogonal to) the lengthwise direction of semiconductor layer stack 110. For example, dummy gates 130 extend along the y-direction, having a length along the y-direction, a width along the x-direction, and a height along the z-direction. Dummy gates 130 may extend substantially parallel to one another. In FIG. 2A (e.g., the X-Z plane), each dummy gate 130 is disposed on top of a respective channel region, and each dummy gate 130 is disposed between respective source/drain regions. In FIG. 3B (e.g., the Y-Z plane), each dummy gate 130 wraps a respective channel region (e.g., disposed over the top and sidewalls thereof), and each dummy gate 130 may be disposed over tops of substrate isolation structures 125.

Dummy gates 130 may include a dummy gate dielectric, a dummy gate electrode, and a hard mask (which may have a multilayer structure). The dummy gate dielectric includes a dielectric material, such as silicon oxide, a high-k dielectric material, other suitable dielectric material, or combinations thereof. For example, the dummy gate dielectric is an oxide layer. The dummy gate electrode includes a suitable dummy gate material, such as polysilicon. Dummy gates 130 are formed by deposition processes, lithography processes, etching processes, other suitable processes, or combinations thereof. For example, a first deposition process may be performed to form a dummy gate dielectric layer over device 100, a second deposition process may be performed to form a dummy gate electrode layer over the dummy gate dielectric layer, and a third deposition process may be performed to form a hard mask layer over the dummy gate electrode layer. A lithography patterning and etching process may then be performed to pattern the hard mask layer, the dummy gate electrode layer, and the dummy gate dielectric layer to form dummy gates 130, which include the dummy gate dielectric, the dummy gate electrode, and the hard mask. The lithography patterning process may include resist coating (e.g., spin-on coating), soft baking, mask aligning, exposure, post-exposure baking, developing the resist, rinsing, drying (e.g., hard baking), other suitable process, or combinations thereof. The etching process may include a dry etch, a wet etch, other etch process, or combinations thereof.

Referring to FIG. 2B and FIG. 2C (and corresponding FIG. 3C and FIG. 3D), gate spacers 132 are formed adjacent to (i.e., along sidewalls of) dummy gates 130 (FIG. 2B and FIG. 2C (FIG. 3C)) and source/drain recesses (trenches) 140 are formed in source/drain regions of semiconductor layer stack 110 (FIG. 2C (FIG. 3D)). Referring to FIG. 2B, a spacer layer 132′ is formed over device 100. For example, a dielectric layer is formed over semiconductor layer stack 110, substrate isolation structures 125, and dummy gates 130 by a deposition process, such as CVD, PECVD, ALD, PEALD, PVD, other suitable deposition process, or combinations thereof. The dielectric material may include silicon, oxygen, carbon, nitrogen, other suitable spacer constituent, or combinations thereof (e.g., silicon oxide, silicon nitride, silicon oxynitride, silicon carbide, silicon carbonitride, silicon oxycarbide, silicon oxycarbonitride, silicon boron carbonitride, or combinations thereof). In some embodiments, spacer layer 132′ is a single layer, such as a silicon nitride layer. In some embodiments, spacer layer 132′ includes multiple layers, such as a first dielectric layer (e.g., a silicon carbonitride layer) formed by a first deposition process and a second dielectric layer (e.g., a silicon nitride layer) formed by a second deposition process over the first dielectric layer. In some embodiments, spacer layer 132′ has a substantially uniform thickness along tops and sidewalls of dummy gates 130 and semiconductor layer stack 110. In some embodiments, spacer layer 132′ is formed by a conformal deposition process, such that spacer layer 132′ conforms to surfaces of device 100 upon which spacer layer 132′ is deposited (and may thus be referred to as a conformal spacer layer).

As depicted in FIG. 2C, FIG. 3C, and FIG. 3D, processing may further include performing a spacer etch on spacer layer 132′ to form gate spacers 132 along sidewalls of dummy gates 130 (FIG. 2C (FIG. 3C)) and a source/drain etch (e.g., at block 20 of method 10) to form source/drain recesses 140 in source/drain regions of semiconductor layer stack 110 (FIG. 2C (FIG. 3D)). The spacer etch may substantially remove spacer layer 132′ from horizontal (lateral) surfaces, such as tops of semiconductor layer stack 110, tops of substrate isolation structures 125, and tops of dummy gates 130, thereby leaving gate spacers 132 along sidewalls of dummy gates 130. In some embodiments, the spacer etch may remove portions of semiconductor layer stack 110, thereby beginning formation of source/drain recesses 140. In some embodiments, the spacer etch selectively removes spacer layer 132′ with respect to dummy gates 130, substrate isolation structures 125, and semiconductor layer stack 110. For example, the spacer etch may remove spacer layer 132′ without (or negligibly) removing dummy gates 130, substrate isolation structures 125, and semiconductor layer stack 110. In some embodiments, gate spacers 132 include more than one set of spacers, such as seal spacers, offset spacers, sacrificial spacers, dummy spacers, main spacers, or combinations thereof. Implantation, diffusion, and/or annealing processes may be performed to form lightly doped source and drain features and/or heavily doped source and drain features in source/drain regions of semiconductor layer stack 110 before and/or after forming gate spacers 132.

The source/drain etch removes portions of semiconductor layer stack 110 that are not covered by dummy gates 130 and gate spacers 132 to form source/drain recesses 140. The source/drain etch may remove semiconductor layers 115 and semiconductor layers 120 in source/drain regions of semiconductor layer stack 110, and source/drain recesses 140 may expose mesa 105′. The source/drain etch may further remove some, but not all, of mesa 105′ in the source/drain regions of semiconductor layer stack 110, such that source/drain trenches 140 extend into but not through mesa 105′. In the depicted embodiment, source/drain recesses 140 extend through semiconductor layer stack 110 to a depth d in mesa 105′, and source/drain recesses 140 have a depth D between the top of semiconductor layer stack 110 and bottoms of source/drain recesses 140. Depth D may be a sum of a height h of semiconductor layer stack 110 and depth d of source/drain recesses 140 in mesa 105′. A width W of source/drain recesses 140 is between sidewalls of adjacent channel regions of semiconductor layer stack 110.

When source/drain recesses 140 extend into mesa 105′ and/or substrate 105, channel regions of semiconductor layer stack 110 may have projecting portions (which may be referred to as mesas 105P′) formed from mesa 105′ and/or substrate 105, while recesses are formed in mesa 105′ and/or substrate 105 in source/drain regions of the semiconductor layer stack 110. In some embodiments, source/drain recesses 140 extend below tops of substrate isolation structures 125. The source/drain etch is a dry etch, a wet etch, other suitable etch, or combinations thereof. In some embodiments, the source/drain etch is a multistep etch process, such as a source/drain etch that alternates etchants to separately and alternately remove semiconductor layers 115 and semiconductor layers 120. In some embodiments, source/drain etch parameters (e.g., etchant thereof) are configured to selectively remove semiconductor materials (i.e., semiconductor layer stack 110) with negligible (to no) removal of dielectric materials (e.g., dummy gates 130 (e.g., hard masks thereof), gate spacers 132, fin spacers, substrate isolation structures 125, etc.). In some embodiments, the spacer etch and the source/drain etch are a single etch process. In some embodiments, the spacer etch and the source/drain etch are separate, sequential etch processes.

Referring to FIGS. 2D-2F (and FIGS. 3E-3G corresponding therewith), inner spacers 145 are formed under gate spacers 132 between semiconductor layers 120 and along sidewalls of semiconductor layers 115. Inner spacers 145 separate semiconductor layers 120 from one another and separate bottommost semiconductor layers 120 from mesa 105′. Referring to FIG. 2D and FIG. 3E, an etching process is performed that selectively etches semiconductor layers 115 exposed by source/drain recesses 140 with negligible (to no) etching of semiconductor layers 120, mesa 105′, dummy gates 130, gate spacers 132, substrate isolation structures 125, or combinations thereof. The etching process forms gaps 148 between semiconductor layers 120 and between semiconductor layers 120 and mesa 105′. Gaps 148 are under gate spacers 132, such that semiconductor layers 120 are suspended under gate spacers 132 and separated from one another by gaps 148. In some embodiments, gaps 148 may extend at least partially under dummy gates 130. The etching process is configured to laterally etch (e.g., along the x-direction and/or the y-direction) semiconductor layers 115. In the depicted embodiment, the etching process reduces lengths of semiconductor layers 115 along the x-direction. The etching process is a dry etch, a wet etch, other suitable etching process, or combinations thereof.

Referring to FIG. 2E and FIG. 3F, a deposition process forms a spacer layer 145′ over device 100, including over features of device 100 that form source/drain recesses 140 (e.g., semiconductor layers 115, semiconductor layers 120, and mesa 105′). Spacer layer 145′ may partially fill source/drain recesses 140. In some embodiments, the deposition process is configured to fill gaps 148 with spacer layer 145′. Referring to FIG. 2F and FIG. 3G, an inner spacer etch may then be performed that selectively etches spacer layer 145′ to form inner spacers 145, which fill gaps 148, with negligible (to no) etching of semiconductor layers 120, mesa 105′, dummy gates 130, gate spacers 132, substrate isolation structures 125, or combinations thereof. Spacer layer 145′ (and thus inner spacers 145) includes a material that is different than a material of semiconductor layers 120, a material of mesa 105′, a material of substrate isolation structures 125, a material of dummy gates 130, materials of gate spacers 132, or combinations thereof to achieve desired etching selectivity during the inner spacer etch. In some embodiments, spacer layer 145′ includes a dielectric material that includes silicon, oxygen, carbon, nitrogen, other suitable dielectric constituent, or combinations thereof (e.g., silicon nitride, silicon carbonitride, silicon oxycarbonitride, silicon oxycarbide, other suitable material, or combinations thereof). In some embodiments, spacer layer 145′ includes a low-k dielectric material. In some embodiments, p-type dopants and/or n-type dopants are introduced into the dielectric material, and spacer layer 145′ (and thus inner spacers 145) includes a doped dielectric material. The inner spacer etch is a dry etch, a wet etch, other suitable etch, or combinations thereof.

Referring to FIGS. 2F-2J (and corresponding FIGS. 3G-3J, respectively), method 10 includes forming source/drain structures 150 having bottom insulation in source/drain recesses 140. For example, method 10 includes forming a base semiconductor layer in the source/drain recess at block 25, such as undoped epitaxial layers 152 in source/drain recesses 140 (FIG. 2F and FIG. 3G); forming an insulator layer in the source/drain recess over the base semiconductor layer at block 30, such as insulator layers 154 over undoped epitaxial layers 152 in source/drain recesses 140 (FIG. 2G, FIG. 2H, and FIG. 3H); forming a break (also referred to as an opening) in the insulator layer that exposes the base semiconductor layer at block 35, such as breaks 155E in insulator layers 154 that expose undoped epitaxial layers 152 (FIG. 2I and FIG. 3I); and forming one or more semiconductor layers in the source/drain recess over the insulator layer and the base semiconductor layer at block 40, such as epitaxial layers 156 and epitaxial layers 158 over insulator layers 154 and undoped epitaxial layers 152 in source/drain recesses 140 (FIG. 2J and FIG. 3J). The one or more semiconductor layers may be doped and fill remainders of source/drain recesses 140. Accordingly, each source/drain structure 150 may include a respective undoped epitaxial layer 152, a respective insulator layer 154, a respective epitaxial layer 156, and a respective epaxial layer 158.

Referring to FIG. 2F and FIG. 3G, undoped epitaxial layers 152 are formed in bottom portions of source/drain recesses 140. Undoped epitaxial layers 152 are disposed on mesas 105P′ and/or mesa 105′, and undoped epitaxial layers 152 partially fill bottom portions of source/drain recesses 140 formed by substrate 105. Undoped epitaxial layers 152 are dopant-free. For example, no intentional doping is performed when forming undoped epitaxial layers (for example, by an epitaxial growth process). Undoped epitaxial layers 152 may provide high resistance paths at bottoms of source/drain recesses 140, thereby suppressing leakage current into substrate 105. Undoped epitaxial layers 152 include silicon, germanium, silicon germanium, other suitable semiconductor materials, or combinations thereof. In some embodiments, undoped epitaxial layers 152 include dopant-free silicon or dopant-free silicon germanium (i.e., substantially free of n-type dopants and p-type dopants). For purposes of the present disclosure, semiconductor materials having dopant concentrations less than about 5×10¹⁸ cm⁻³ are considered undoped, unintentionally doped (UID), and/or dopant-free.

Undoped epitaxial layers 152 have recessed top surfaces 152R, and source/drain recesses 140 extend a depth d1 into mesa 105′ after forming undoped epitaxial layers 152. Depth d1 is less than depth d. Undoped epitaxial layers 152 may have U-shaped structures, such as where recessed top surfaces 152R are concave surfaces. In the depicted embodiment, undoped epitaxial layers 152 have a substantially uniform thickness. For example, a thickness of bottom portions (e.g., forming curved segments of the U-shaped structures) may be substantially the same as a thickness of sidewall portions (e.g., forming vertically extending segments of the U-shaped structures). In some embodiments, undoped epitaxial layers 152 have a varied thickness. For example, undoped epitaxial layers 152 may have bottom portions that are thicker than their sidewall portions, and a thickness of the bottom portions may be a difference between depth d and depth d1. In some embodiments, undoped epitaxial layers 152 are trough-shaped structures, V-shaped structures, or other shaped structures having recessed top surfaces.

In some embodiments, undoped epitaxial layers 152 are formed by a selective epitaxial growth (SEG) process that selectively deposits (grows) semiconductor material (e.g., silicon or silicon germanium) from semiconductor surfaces (e.g., mesas 105P′, mesa 105′, substrate 105, and/or semiconductor layers 120) while limiting (or preventing) growth of semiconductor material from dielectric surfaces and/or non-semiconductor surfaces (e.g., inner spacers 145, dummy gates 130, gate spacers 132, and/or substrate isolation structures 125). The SEG process may implement CVD deposition techniques (e.g., vapor-phase epitaxy (VPE), ultra-high vacuum CVD (UHV-CVD), LPCVD, PECVD, or the like), molecular beam epitaxy, other suitable SEG process, or combinations thereof. Epitaxial growth conditions are tuned to achieve epitaxial growth on semiconductor surfaces with negligible to no growth on dielectric surfaces and/or non-semiconductor surfaces. In the depicted embodiment, epitaxial growth conditions are tuned to provide undoped epitaxial layers 152 with top surfaces that are level with and/or below a bottom surface of semiconductor layer stack (e.g., bottom surfaces of bottommost semiconductor layers 115), and the epitaxial growth conditions are further tuned to provide undoped epitaxial layers 152 with recessed top surfaces 152R. In other words, undoped epitaxial layers 152 may not extend beyond top surfaces of mesas 105P′, in some embodiments. The epitaxial growth conditions include deposition gas composition (e.g., type of silicon-containing precursor and/or type of germanium-containing precursor), carrier gas composition (e.g., type of inert gas), etch gas composition (e.g., type of etchant-containing precursor), deposition gas flow rate, carrier gas flow rate, etchant gas flow rate, deposition time, deposition pressure, deposition temperature, source power, etch time, etch pressure, etch temperature, source power, bias voltage, bias power, other suitable epitaxial growth parameters, or combinations thereof. In some embodiments, the SEG process is configured as a bottom-up deposition process, such that undoped epitaxial layers 152 grow from mesas 105P′, mesa 105′, and/or substrate 105 with minimal (to no) growth from semiconductor layers 120. In some embodiments, an etching process is performed after the SEG process to remove any semiconductor material (e.g., silicon and/or germanium) that may have formed on semiconductor layers 120. The post-deposition etch may be a dry etch, a wet etch, other suitable etch, or combinations thereof.

Referring to FIG. 2G and FIG. 2H (and corresponding FIG. 3H), insulator layers 154 may be formed by depositing an insulator material 154′ over device 100 (FIG. 2G) and etching insulator material 154′ to form insulator layers 154 in bottoms of source/drain recesses 140 (FIG. 2H and FIG. 3H). Referring to FIG. 2G, insulator material 154′ is disposed on tops of the gate structures (e.g., top surfaces of gate spacers 132 and top surfaces of dummy gates 130), sidewalls of the gate structures (e.g., sidewalls of gate spacers 132), sidewalls of semiconductor layers 120, sidewalls of inner spacers 145, and recessed top surfaces 152R of undoped epitaxial layers 152. Insulator material 154′ partially fills bottom portions of source/drain recesses 140, and insulator material 154′ conforms to undoped epitaxial layers 152, such that insulator material 154′ over undoped epitaxial layers 152 may also have recessed top surfaces 154R. Source/drain recesses 140 thus extend a depth d2 (which is less than depth d1) into mesa 105′ after forming insulator material 154′. In some embodiments, insulator material 154′ is a silicon-comprising dielectric material, such as silicon nitride, silicon oxynitride, silicon oxycarbonitride, silicon oxycarbide, silicon carbonitride, other silicon-comprising dielectric material (which may include silicon and nitrogen, carbon, oxygen, other suitable dielectric constituent, or combinations thereof), or combinations thereof. In some embodiments, insulator material 154′ is a metal-comprising dielectric material, such as a metal oxide material (e.g., aluminum oxide and/or hafnium oxide) and/or a metal nitride material. In some embodiments, insulator material 154′ is a doped semiconductor material that includes an opposite type of dopant than doped semiconductor layers of source/drain structures 150, such as a dopant that is an opposite type of dopant included in epitaxial layers 156 and/or epitaxial layers 158. For example, where source/drain structures 150 are portions of p-type transistors having p-type doped semiconductor layers, insulator material 154′ may be an n-type doped semiconductor material, such as phosphorous-doped silicon. In another example, where source/drain structures 150 are portions of n-type transistors having n-type doped semiconductor layers, insulator material 154′ may be p-doped semiconductor material, such as boron-doped silicon.

In the depicted embodiment, insulator material 154′ is formed by a conformal deposition process, and insulator material 154′ may have a substantially uniform thickness over vertically oriented surfaces of device 100, horizontally oriented surfaces of device 100, or combinations thereof. For example, a thickness of portions of insulator material 154′ along sidewalls of the gate structures, sidewalls of semiconductor layers 120, and sidewalls of inner spacers 145 may be substantially the same as a thickness of portions of insulator material 154′ along tops of the gate structures, which may be substantially the same as a thickness of portions of insulator material 154′ along recessed top surfaces 152R of undoped epitaxial layers 152. Insulator material 154′ may thus be referred to as a conformal insulator layer. In some embodiments, insulator material 154′ is formed by ALD. In some embodiments, insulator material 154′ is formed by CVD, PVD, other suitable process, or combinations thereof. In some embodiments, a thickness of insulator material 154′ over vertically oriented surfaces may be less than a thickness of insulator material 154′ over horizontally oriented surfaces.

Referring to FIG. 2H and FIG. 3H, an etching process removes insulator material 154′ from portions of device 100 above mesas 105P′. Insulator material 154′ remaining at or below top surfaces of mesas 105P′ provides insulator layers 154 in the bottoms of source/drain recesses 140. In some embodiments, insulator material 154′ is silicon nitride, and insulator layers 154 are silicon nitride layers. In some embodiments, the etching process removes insulator material 154′ from sidewalls of the gate structures, sidewalls of semiconductor layers 120, sidewalls of inner spacers 145, and tops of the gate structures, but not from recessed top surfaces 152R. In the depicted embodiment, insulator layers 154 completely cover recessed top surfaces 152R of undoped epitaxial layers 152, insulator layers 154 have recessed top surfaces 154R, and insulator layers 154 have substantially uniform thicknesses (e.g., a thickness of central portions of insulator layers 154 is substantially the same as thicknesses of edge/end portions of insulator layers 154). In some embodiments, portions of insulator layers 154 that cover topmost surfaces of undoped epitaxial layers 152 may be disposed above top surfaces of mesas 105P′ and adjacent to bottommost inner spacers 145. The etching process is a dry etch, a wet etch, other suitable etch, or combinations thereof. In some embodiments, parameters of the etching process are tuned to remove vertically oriented portions of insulator material 154′, such as that on sidewalls of the gate structures, sidewalls of semiconductor layers 120, and sidewalls of inner spacers 145. In such embodiments, as a result of etch loading effects, the etching process may also remove horizontally oriented portions of insulator material 154′ on tops of the gate structures, but not (or minimally) horizontally oriented portions and/or vertically oriented portions of insulator material 154′ on undoped epitaxial layers 152 in bottoms of source/drain recesses 140 (i.e., the etching process may thin but not substantially remove such portions). In some embodiments, the etching process uses a fluorine-based etchant including fluorine (F₂), hydrogen fluoride (HF), nitrogen trifluoride (NF₃), other fluorine-containing etchant, or combinations thereof. In some embodiments, parameters of the deposition process used to form insulator material 154′ are tuned to provide vertically oriented portions and horizontally oriented portions of insulator material 154′ with different etch selectivity and/or different thicknesses to facilitate improved, targeted removal of insulator material 154′ above mesas 105P′.

Referring to FIG. 2I and FIG. 3I, breaks 155E are formed in insulator layers 154 that expose undoped epitaxial layers 152. In the depicted embodiment, an etching process removes edges/ends of insulator layers 154 to expose edges/ends 152E of undoped epitaxial layers 152, such that insulator layers 154 partially, instead of completely, cover recessed top surfaces 152R of undoped epitaxial layers 152. The etching process may modify a thickness profile of insulator layers 154. For example, the etching process may thin remaining edges/ends of insulator layers 154, such that a thicknesses of side/edge portions of insulator layers 154 is less than a thickness of central portions of insulator layers 154, such as depicted. The etching process may also thin exposed edges/ends 152E of undoped epitaxial layers 152, and a thickness of side/edge portions of undoped epitaxial layers 152 may be less than a thickness of central portions of undoped epitaxial layers 152, such as depicted. In some embodiments, the thickness profile of insulator layers 154 is not modified by the etching process. For example, insulator layers 154 may have substantially uniform thicknesses after forming breaks 155E. In some embodiments, the thickness profile of undoped epitaxial layers 152 is not modified by the etching process. For example, exposed edges 152E and covered portions (e.g., central portions) of undoped epitaxial layers 152 may have the same thickness after forming breaks 155E.

The etching process is a dry etch, a wet etch, other suitable etch, or combinations thereof. In the depicted embodiment, parameters of the etching process are tuned to provide targeted removal of edges/ends of insulator layers 154 and negligible (to no) removal of central portions of insulator layers 154, such that a majority of undoped epitaxial layers 152 remains covered by insulator layers 154. In some embodiments, parameters of the etching process (e.g., etchant thereof) are configured to selectively remove insulator layers 154 with negligible (to no) removal of semiconductor layers 120, dummy gates 130 (e.g., hard masks thereof), gate spacers 132, inner spacers 145, undoped epitaxial layers 152, substrate isolation structures 125, or combinations thereof. In some embodiments, the etching process uses a nitrogen-based etchant including nitrogen (N₂), ammonia (NH₃), other nitrogen-containing etchant, or combinations thereof. In some embodiments, the etching process uses an etchant that includes hydrogen and nitrogen, such as an N₂/H₂ etchant. In some embodiments, the etching process implements an etch mask to achieve targeted removal of edges/ends of insulator layers 154. In some embodiments, the etch mask is formed by depositing an etch mask layer(s) (e.g., one or more materials resistant to an etchant for removing insulator layers 154) and performing a lithography process to pattern the etch mask layer(s), such that the etch mask layer(s) has openings therein that expose edges/ends of insulator layers 154 and the etch mask layer(s) covers the gate structures (e.g., top surfaces thereof) and central portions of insulator layers 154 (which are to remain over undoped epitaxial layers 152 and provide bottom source/drain insulation). The etch mask layer(s) may protect the gate structures and central portions of insulator layers 154 while the etching process removes the exposed edges/ends of insulator layers 154. In some embodiments, the etch mask layer(s) may cover and/or protect sidewalls of semiconductor layers 120 and/or sidewalls of inner spacers 145 during the etching process.

Referring to FIG. 2J and FIG. 3J, epitaxial layers 156 are formed over semiconductor layers 120, undoped epitaxial layers 152, and insulator layers 154. Epitaxial layers 156 partially fill source/drain recesses 140. Because breaks 155E are formed in insulator layers 154, epitaxial layers 156 are formed on and/or grown from both semiconductor layers 120 and undoped epitaxial layers 152, instead of semiconductor layers 120 alone, and epitaxial layers 156 have sidewall epitaxial portions and bottom epitaxial portions. The sidewall epitaxial portions may be formed directly on and/or physically contact sidewalls of semiconductor layers 120, and the bottom epitaxial portions may be formed directly on and/or physically contact exposed edges/ends 152E of undoped epitaxial layers 152. Adjacent sidewall epitaxial portions are not connected to one another, and bottom epitaxial portions are not connected to one another and/or to sidewall epitaxial portions. Epitaxial layers 156 thus have discrete and separate epitaxial portions (i.e., epitaxial layers 156 are discontinuous). In some embodiments, one or more of the sidewall epitaxial portions wrap a respective semiconductor layer 120, such that the sidewall epitaxial portions are also formed directly on and/or physically contact tops and/or bottoms of the respective semiconductor layer 120. In some embodiments, the bottom epitaxial portions do not extend above top surfaces of mesas 105P′. In some embodiments, the bottom epitaxial portions extend above top surfaces of mesas 105P′. In some embodiments, the sidewall epitaxial portions and/or the bottom epitaxial portions extend over and/or physically contact inner spacers 145. In some embodiments, the bottom epitaxial portions extend over and/or physically contact insulator layers 154. In some embodiments, at least one of the bottom epitaxial portions is connected to a respective one of the bottommost sidewall epitaxial portions. In some embodiments, one or more of the adjacent sidewall epitaxial portions are connected.

Epitaxial layers 158 are formed over epitaxial layers 156 and insulator layers 154, and epitaxial layers 158 may fill remainders of source/drain recesses 140. Epitaxial layers 158 are separated from semiconductor layers 120 by the sidewall epitaxial portions of epitaxial layers 156, and epitaxial layers 158 are separated from undoped epitaxial layers 152 by bottom epitaxial portions of epitaxial layers 156. In some embodiments, epitaxial layers 158 may be separated from inner spacers 145 by the sidewall epitaxial portions and/or the bottom epitaxial portions of epitaxial layers 156. In some embodiment, epitaxial layers 158 wrap epitaxial layers 156. In the depicted embodiment, because undoped epitaxial layers 152 and insulator layers 154 have recessed top surfaces, epitaxial layers 156 and epitaxial layers 158 fill remainders of the bottom portions of source/drain recesses 140 formed by substrate 105, such that epitaxial layers 156 and epitaxial layers 158 are disposed below and above tops surfaces of mesas 105P′.

Epitaxial layers 156 and epitaxial layers 158 include silicon, germanium, silicon germanium, other suitable semiconductor materials, or combinations thereof. In some embodiments, epitaxial layers 156 and epitaxial layers 158 include the same semiconductor material but with different constituent concentrations. For example, epitaxial layers 156 and epitaxial layers 158 may include silicon germanium and p-type dopant (e.g., boron and/or gallium), but different germanium concentrations and/or different p-type dopant concentrations. In some embodiments, epitaxial layers 156 have a smaller germanium concentration (e.g., Ge %) and/or a smaller p-type dopant concentration (e.g., B %) than epitaxial layers 158 to reduce crystalline dislocation, reduce other crystalline defects, maximize strain (and thereby enhance carrier mobility, which increases drive current), or combinations thereof. In some embodiments, a germanium concentration in epitaxial layers 156 is about 10% to about 20%, and a germanium concentration in epitaxial layers 158 is about 30% to about 60%. In some embodiments, epitaxial layers 156 have a p-type dopant concentration (e.g., a boron concentration) of about 1×10²⁰ cm⁻³ to about 5×10²⁰ cm⁻³, and epitaxial layers 158 have a p-type dopant concentration (e.g., boron concentration) of about 5×10²⁰ cm⁻³ to about 2×10²¹ cm⁻³. In another example, epitaxial layers 156 and epitaxial layers 158 may include silicon and n-type dopant (e.g., phosphorus, arsenic, and/or antimony), but different n-type dopant concentrations. The present disclosure contemplates various embodiments where epitaxial layers 156 and epitaxial layers 158 have different semiconductor materials with same or different constituent concentrations. In some embodiments, undoped epitaxial layers 152 have different lattice constants and/or different lattice structures than epitaxial layers 158, and epitaxial layers 156 function as buffer layers. For example, a lattice constant and/or a lattice structure of epitaxial layers 156 may gradually change from a lattice constant and/or a lattice structure similar to that of undoped epitaxial layers 152 to a lattice constant and/or a lattice structure similar to that of epitaxial layers 158.

Epitaxial layers 156 may be deposited on and/or grown from semiconductor layers 120 and undoped epitaxial layers 152, and epitaxial layers 158 may be deposited on and/or grown from epitaxial layers 156. In some embodiments, epitaxial layers 156 and epitaxial layers 158 are formed by respective SEG processes, which may implement CVD deposition techniques (e.g., VPE, UHV-CVD, LPCVD, PECVD, or the like), molecular beam epitaxy, other suitable SEG process, or combinations thereof. The SEG processes may use gaseous and/or liquid precursors that interact with the composition of semiconductor layers 120, undoped epitaxial layers 152, epitaxial layers 156, or combinations thereof. Epitaxial growth/deposition conditions, such as those described herein, are tuned to selectively deposit (grow) semiconductor material (e.g., silicon or silicon germanium) on semiconductor surfaces (e.g., semiconductor layers 120, undoped epitaxial layers 152, and/or epitaxial layers 156) while limiting (or preventing) growth of semiconductor material from dielectric surfaces and/or non-semiconductor surfaces (e.g., inner spacers 145, dummy gates 130, gate spacers 132, and/or substrate isolation structures 125). In some embodiments, epitaxial layers 156 and/or epitaxial layers 158 are doped during deposition (i.e., in-situ doping), such as by adding dopants to a source material of the SEG processes. In some embodiments, epitaxial layers 156 and/or epitaxial layers 158 are doped after deposition, such as by an ion implantation process. In some embodiments, annealing is performed to activate dopants in epitaxial layers 156 and/or epitaxial layers 158.

In some embodiments, an SEG process, such as a remote plasma CVD (RPCVD) process, introduces a silicon-containing precursor, a germanium-containing precursor, and a carrier precursor/gas into a process chamber, where the precursors interact with one another and/or semiconductor surfaces of device 100 to form epitaxial layers 156 and/or epitaxial layers 158. The silicon-containing precursor may include SiH₄, Si₂H₆, DCS, SiHCl³, SiCl⁴, other suitable silicon-containing precursors, or combinations thereof. The germanium-containing precursor may include GeH₄, Ge₂H₆, GeCl₄, GeCl₂, other suitable germanium-containing precursors, or combinations thereof. The carrier gas may be an inert gas, such as H₂. In some embodiments, the SEG process introduces a dopant-containing precursor into the process chamber to facilitate in-situ doping of epitaxial layers 156 and/or epitaxial layers 158. The dopant-containing precursor may include boron (e.g., B₂H₆), phosphorous (e.g., PH₃), arsenic (e.g., AsH₃), other suitable dopant-containing precursor, or combinations thereof. In some embodiments, the SEG process introduces an etchant-containing precursor into the process chamber to prevent or limit growth of silicon material and/or germanium material on dielectric surfaces and/or non-semiconductor surfaces as described herein. In such embodiments, parameters of the SEG process may be tuned to ensure net deposition of semiconductor material on semiconductor surfaces. The etchant-containing precursor may include Cl₂, HCl, other etchant-containing precursors that can facilitate desired semiconductor material (e.g., silicon and/or germanium) growth selectivity, or combinations thereof. In some embodiments, the SEG process introduces the silicon-containing precursor, but not the germanium-containing precursor, such as where source/drain structures 150 are configured for n-type transistors. In some embodiments, epitaxial layers 156 and epitaxial layers 158 are formed by separate SEG processes. In some embodiments, epitaxial layers 156 and epitaxial layers 158 are formed by a single SEG process, where the epitaxial growth/deposition parameters are tuned to provide epitaxial layers 156 and epitaxial layers 158 with different compositions (e.g., different dopant concentrations and/or different germanium concentrations) and/or thicknesses.

Configuring transistors with bottom insulation breaks increases semiconductor surfaces from which doped source/drain layers (e.g., epitaxial layers 158 and/or epitaxial layers 156) may be grown/deposited on (e.g., by exposing undoped epitaxial layers), which improves growth/deposition of doped source/drain layers, while preserving performance gains provided to the transistors by bottom insulation (e.g., improved AC gain in p-type transistors). In some embodiments, the improved growth/deposition recovers source/drain strain/stress loss that may occur when bottoms of source/drain recesses are formed by bottom insulation (e.g., insulator layers 154) alone. In some embodiments, the etching process exposes about 5% to about 15% of a surface area of a respective undoped epitaxial layer 152 (i.e., about 85% to about 95% of a surface area of a respective undoped epitaxial layer 152 remains covered by its respective insulator layer 154 after breaks (edge or center) are formed therein). Exposing less than 5% surface area of the respective undoped epitaxial layer 152 may provide negligible increase in semiconductor surface area from which epitaxial material may grow and thus provide negligible to no improvement in epitaxial growth (e.g., of epitaxial layers 158) and source/drain strain recovery. Exposing greater than 15% surface area of the respective undoped epitaxial layer 152 may degrade performance improvements obtained by incorporating bottom insulation (e.g., insulator layers 154) into source/drain structures too much. Different embodiments may have different advantages, and no particular advantage is required of any embodiment.

Referring to FIG. 2K and FIG. 3K, fabrication of device 100 may further include forming a dielectric layer 160 over device 100, such as over source/drain structures 150 and substrate isolation structures 125. Dielectric layer 160 may fill spaces between the adjacent gate structures, such as spaces between gate spacers 132 thereof, and spaces between adjacent source/drain structures 150. Forming dielectric layer 160 may include depositing a contact etch stop layer (CESL) over device 100, depositing an interlayer dielectric (ILD) layer over the CESL, and performing a CMP and/or other planarization process until reaching dummy gates 130. The planarization process may remove a portion of dummy gates 130, such as hard masks thereof, to expose underlying dummy gate electrodes thereof, such as polysilicon gates thereof. Heights of dummy gates 130 may be reduced by the planarization process. The CESL and the ILD layer are formed by CVD and/or other suitable methods. In some embodiments, the ILD layer is formed by FCVD, HARP, HDPCVD, or combinations thereof.

The ILD layer includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass, fluorosilicate glass, xerogel, aerogel, amorphous fluorinated carbon, parylene, benzocyclobutene-based (BCB) dielectric material, polyimide, other suitable dielectric material, or combinations thereof. In some embodiments, the ILD layer includes a low-k dielectric material having a dielectric constant that is less than a dielectric constant of silicon dioxide (e.g., k<3.9). In some embodiments, the ILD layer includes a dielectric material having a dielectric constant that is less than about 2.5 (i.e., an extreme low-k (ELK) dielectric material), such as porous silicon dioxide, silicon carbide, carbon-doped oxide (e.g., a SiCOH-based material having, for example, Si—CH₃ bonds), or combinations thereof, each of which is tuned/configured to exhibit a dielectric constant less than about 2.5. The CESL includes a material different than the ILD layer, such as a dielectric material that is different than the dielectric material of the ILD layer. For example, where the ILD layer includes a silicon- and- oxygen comprising low-k dielectric material, the CESL may include silicon and nitrogen, such as silicon nitride or silicon oxynitride. The ILD layer and/or the CESL may have a multilayer structure and/or include multiple dielectric materials.

A gate replacement process may then be performed to replace dummy gates 130 with a gate stack 170A and a gate stack 170B, respectively. For example, dummy gates 130 are removed to form gate openings (formed between gate spacers 132 and/or inner spacers 145) that expose channel regions of semiconductor layer stacks 110 (e.g., semiconductor layers 120 and semiconductor layers 115). In some embodiments, an etching process may selectively remove dummy gates 130 with respect to dielectric layer 160, gate spacers 132, inner spacers 145, semiconductor layers 115, semiconductor layers 120, or combinations thereof. In other words, the etching process removes dummy gates 130 with negligible (to no) removal of dielectric layer 160, gate spacers 132, inner spacers 145, semiconductor layers 115, semiconductor layers 120, or combinations thereof. The etching process is a dry etch, a wet etch, other suitable etch process, or combinations thereof. In some embodiments, the etching process uses a patterned mask layer as an etch mask, where the patterned mask layer covers dielectric layer 160 and/or gate spacers 132 but has openings therein that expose dummy gates 130.

During the gate replacement process, before forming gate stack 170A and gate stack 170B in the gate openings, a channel release process may be performed to form suspended channel layers. For example, semiconductor layers 115 exposed by the gate openings are selectively removed to form air gaps between semiconductor layers 120 and between semiconductor layers 120 and mesas 105P′, thereby suspending semiconductor layers 120 in channel regions. In the depicted embodiment, each channel region has three suspended semiconductor layers 120, which are referred to hereafter as channel layers 120′, vertically stacked along the z-direction for providing three channels through which current can flow between respective source/drain structures 150 during operation of transistors of device 100. In some embodiments, an etching process selectively etches semiconductor layers 115 with minimal (to no) etching of semiconductor layers 120, mesas 105P′, gate spacers 132, inner spacers 145, dielectric layer 160, or combinations thereof. In some embodiments, an etchant is selected for the etch process that etches silicon germanium (i.e., semiconductor layers 115) at a higher rate than silicon (i.e., semiconductor layers 120 and mesas 105P′) and dielectric materials (i.e., gate spacers 132, inner spacers 145, and/or dielectric layer 160) (i.e., the etchant has a high etch selectivity with respect to silicon germanium). The etching process is a dry etch, a wet etch, other suitable etch process, or combinations thereof. In some embodiments, before performing the etching process, an oxidation process may be implemented to convert semiconductor layers 115 into silicon germanium oxide features, where the etching process then removes the silicon germanium oxide features. In some embodiments, during and/or after removing semiconductor layers 115, an etching process is performed to modify a profile of semiconductor layers 120 to achieve target dimensions and/or target shapes for channel layers 120′.

Gate stack 170A and gate stack 170B (also referred to as high-k/metal gates) may then be formed in the gate openings. Gate stack 170A and gate stack 170B are disposed between respective gate spacers 132. Gate stack 170A and gate stack 170B are further disposed between respective inner spacers 145. Gate stack 170A and gate stack 170B are further disposed between channel layers 120′ and between channel layers 120′ and mesas 105P′. In the depicted embodiment, where device 100 includes GAA transistors, gate stack 170A and gate stack 170B may surround respective channel layers 120′, for example, in the Y-Z plane. In some embodiments, gate stack 170A and gate stack 170B may wrap and/or partially surround respective channel layers 120′ (i.e., be disposed on at least two sides thereof).

Gate stack 170A includes a gate dielectric 172A, and gate stack 170B includes a gate dielectric 172B. Gate dielectric 172A and gate dielectric 172B are disposed on respective channel layers 120′, mesas 105P′, inner spacers 145, gate spacers 132, substrate isolation structures 125, or combinations thereof. Compositions and/or configurations of gate dielectric 172A and gate dielectric 172 B may be the same as or different. Gate dielectric 172A and gate dielectric 172B each include at least one dielectric gate layer, such as an interfacial layer and/or a high-k dielectric layer. The interfacial layer includes a dielectric material, such as SiO₂, SiGeOₓ, HfSiO, SiON, other dielectric material, or combinations thereof. The high-k dielectric layer includes a high-k dielectric material, which generally refers to dielectric materials having a dielectric constant greater than a dielectric constant of silicon dioxide, such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), HfO₂—Al₂O₃, other high-k dielectric material, or combinations thereof. In some embodiments, gate dielectric 172A and gate dielectric 172B each include a hafnium-based oxide (e.g., HfO₂) layer and/or a zirconium-based oxide (e.g., ZrO₂) layer.

Gate stack 170A further includes a gate electrode 174A disposed over gate dielectric 172A, and gate stack 170B further includes a gate electrode 174B disposed over gate dielectric 172B. Compositions and/or configurations of gate electrode 174A and gate electrode 174B may be the same or different. Gate electrode 174A and gate electrode 174B each include an electrically conductive gate layer, which includes an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments, the electrically conductive gate layer includes a work function layer. The work function layer is a conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, the electrically conductive gate layer includes a bulk layer over the gate dielectric and/or the work function layer. The bulk layer may include Al, W, Cu, Ti, Ta, TiN, TaN, polysilicon, other suitable metal(s) and/or alloys thereof, or combinations thereof. In some embodiments, the electrically conductive gate layer includes a barrier (blocking) layer over the work function layer and/or the gate dielectric. The barrier layer includes a material that may prevent diffusion and/or reaction of constituents between adjacent layers and/or promotes adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

Forming gate stack 170A and gate stack 170B may include depositing gate dielectric material (e.g., interfacial layers, high-k dielectric layers, etc.) that partially fill the gate openings, depositing gate electrode material (e.g., work function layers, barrier layers, bulk layers, etc.) that fill remainders of the gate openings, and performing a planarization process to remove portions of the gate dielectric material and/or portions of the gate electrode material over dielectric layer 160. In some embodiments, fabrication of device 100 may further include etching back gate stack 170A and gate stack 170B and forming hard masks (e.g., self-aligned cap (SAC) structures) over the etched-back gate stack 170A and gate stack 170B. The hard masks include a material that is different than dielectric layer 160 and/or subsequently formed dielectric layers to achieve etch selectivity. In some embodiments, the hard masks include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, the hard masks include metal and oxygen and/or nitrogen, such as aluminum oxide, aluminum nitride, aluminum oxynitride, zirconium oxide, zirconium nitride, hafnium oxide, zirconium aluminum oxide, other metal oxide, other metal nitride, or combinations thereof. Though the depicted embodiment fabricates the gate stack 170A and gate stack 170B according to a gate last process, the present disclosure contemplates embodiments where the metal gate stacks of device 100 may be fabricated according to a gate first process or a hybrid gate last/gate first process.

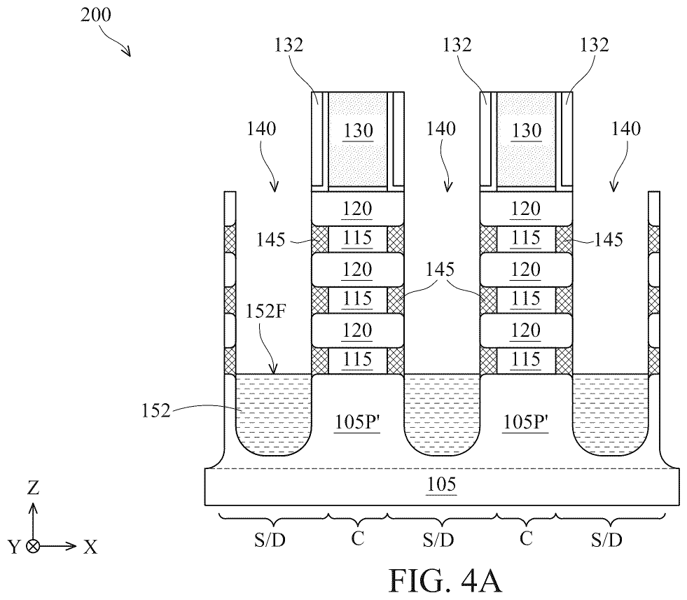

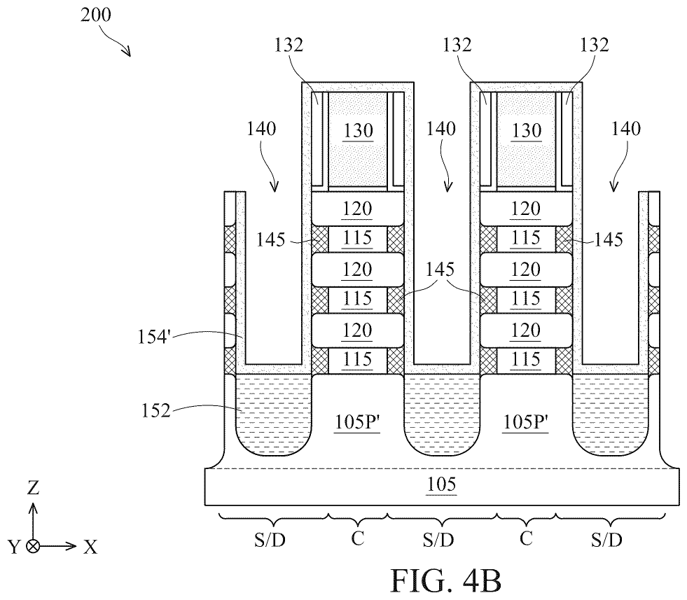

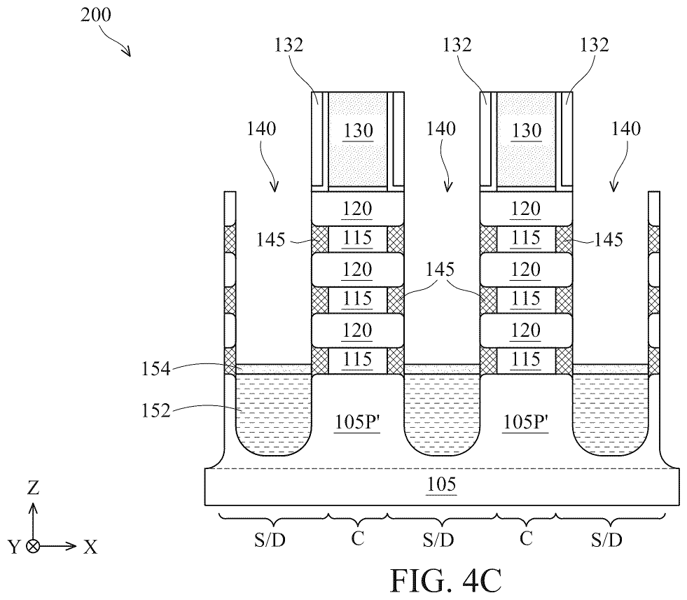

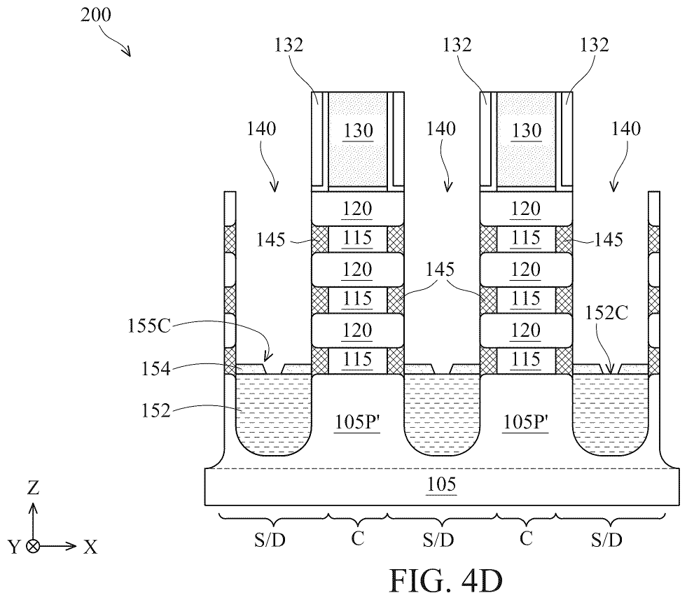

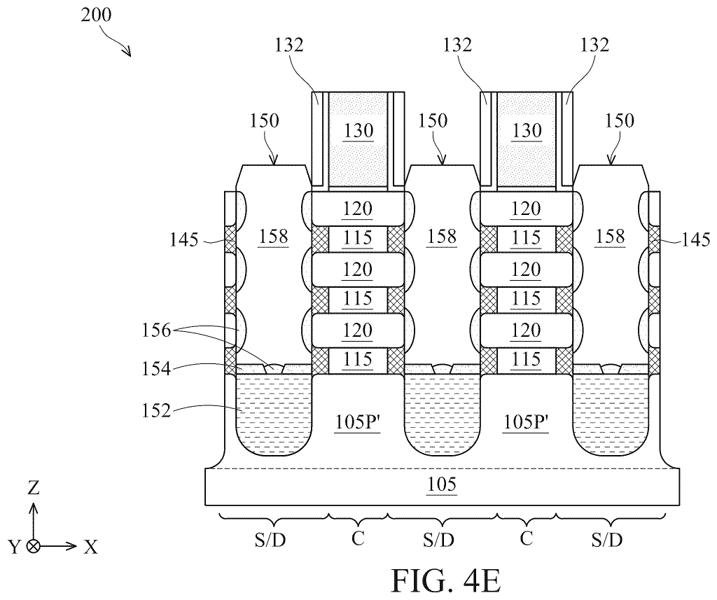

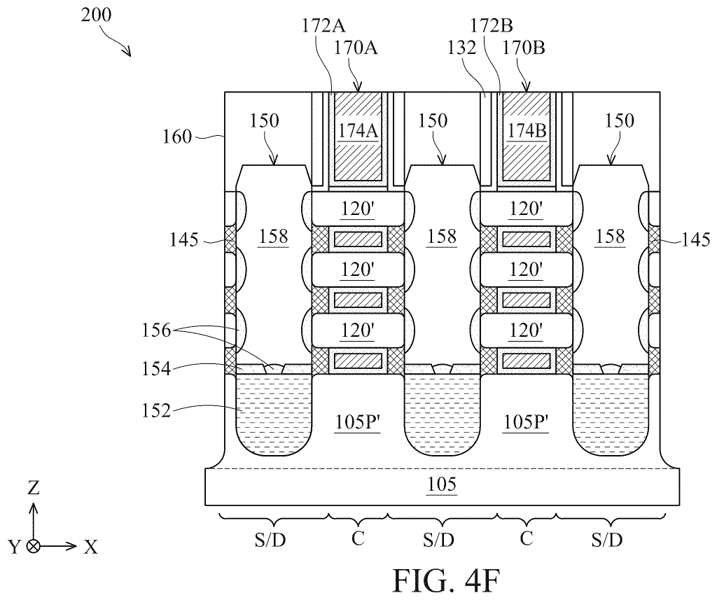

The present disclosure contemplates forming breaks in different locations of insulator layers 154. For example, center breaks, instead of edge breaks, may be formed in insulator layers 154, such as depicted and described with reference to FIGS. 4A-4F. FIGS. 4A-4F are cross-sectional views of a device 200, in portion or entirety, at various stages of fabricating source/drain structures, such as those associated with method 10 in FIG. 1, according to various aspects of the present disclosure. Fabrication of device 200 is similar in many respects to fabrication of device 100. Similar features of device 200 and device 100 are thus identified by the same reference numerals for simplicity and clarity. FIGS. 4A-4F have been simplified for the sake of clarity to better understand the inventive concepts of the present disclosure. Additional features may be added in device 200, and some of the features described below may be replaced, modified, or eliminated in other embodiments of device 200.

Referring to FIG. 4A, device 200 has undergone processing associated with FIGS. 2A-2E, and undoped epitaxial layers 152 are formed in bottom portions of source/drain recesses 140, such as described herein. In the depicted embodiment, undoped epitaxial layers 152 completely fill, instead of partially fill, bottom portions of source/drain recesses 140, and undoped epitaxial layers 152 have substantially flat, planar top surfaces 152F, instead of recessed top surfaces 152R. Undoped epitaxial layers 152 thus have different cross-sectional profiles in device 200. Epitaxial growth conditions may be tuned to substantially fill source/drain recesses 140 of device 200 and provide undoped epitaxial layers 152 with flat top surfaces 152F. In some embodiments, such as depicted, source/drain recesses 140 may not extend into mesa 105′ after forming undoped epitaxial layers 152. For example, flat top surfaces 152F may be about level with top surfaces of mesas 105P′. In another example, undoped epitaxial layers 152 may overfill bottom portions of source/drain recesses 140 and extend above top surfaces of mesas 105P′, such that flat top surfaces 152F thereof are above top surfaces of mesas 105P′.

Referring to FIG. 4B and FIG. 4C, insulator layers 154 may be formed by depositing insulator material 154′ over device 200 (FIG. 4B) and etching insulator material 154′ to form insulator layers 154 over undoped epitaxial layers 152 (FIG. 4C). Referring to FIG. 4B, insulator material 154′ is disposed on tops of the gate structures, sidewalls of the gate structures, sidewalls of semiconductor layers 120, sidewalls of inner spacers 145, and flat top surfaces 152F of undoped epitaxial layers 152. In device 200, because insulator material 154′ conforms to undoped epitaxial layers 152, insulator material 154′ over undoped epitaxial layers 152 may have substantially flat, planar top surfaces 154F, instead of recessed top surfaces 154R.

Referring to FIG. 4C, the etching removes insulator material 154′ from sidewalls of the gate structures, sidewalls of semiconductor layers 120, sidewalls of inner spacers 145, and tops of the gate structures, but not from flat top surfaces 152F of undoped epitaxial layers 152. Insulator layers 154 thus completely cover flat top surfaces 152F, and insulator layers 154 have flat top surfaces 154F. In the depicted embodiment, because undoped epitaxial layers 152 substantially fill bottom portions of source/drain recesses 140, insulator layers 154 are at least partially disposed above top surfaces of mesas 105P′, and insulator layers 154 may be disposed adjacent to and/or physically contact bottommost inner spacers 145. In such embodiments, a thickness of insulator layers 154 above top surfaces of mesas 105P′ is less than a thickness of bottommost semiconductor layers 215 to ensure that insulator layers 154 are not disposed on and/or do not cover sidewalls of bottommost semiconductor layers 220. In some embodiments, insulator layers 154 are fully disposed above top surfaces of mesas 105P′.

Referring to FIG. 4D, breaks 155C are formed in insulator layers 154 that expose undoped epitaxial layers 152. In the depicted embodiment, an etching process removes middle portions of insulator layers 154 to expose centers 152C of undoped epitaxial layers 152, such that insulator layers 154 partially, instead of completely, cover flat top surfaces 152F of undoped epitaxial layers 152. After the etching process, bottoms of source/drain recesses 140 may be formed by exposed centers 152C of undoped epitaxial layers 152 and edges/ends of insulator layers 154. In some embodiments, insulator layers 154 have a width W1 (e.g., their width before the etching process), breaks 155C have a width W2 (which may be a maximum width of breaks 155C), and width W2 is about 1% to about 90% of width W1 (i.e., a ratio of width W2 to width W1 may be about 0.01 to about 0.9). The etching process may modify a thickness profile of insulator layers 154. For example, the etching process may thin remaining middle portions of insulator layers 154, such that a thickness of side/edge portions of insulator layers 154 are greater than a thickness of central portions of insulator layers 154, such as depicted. In some embodiments, insulator layers 154 may have tapered thicknesses that decrease from side/edge portions thereof to central portions thereof. In some embodiments, the thickness profile of insulator layers 154 is not modified by the etching process. For example, insulator layers 154 may have substantially uniform thicknesses after forming breaks 155C. In some embodiments, the etching process may also thin exposed centers 152C of undoped epitaxial layers 152, and a thickness of side/edge portions of undoped epitaxial layers 152 may be greater than a thickness of central portions of undoped epitaxial layers 152. In some embodiments, the thickness profile of undoped epitaxial layers 152 is not modified by the etching process, such as depicted.

In the depicted embodiment, parameters of the etching process are tuned to provide targeted removal of middle portions of insulator layers 154 and negligible (to no) removal of edges/ends of insulator layers 154, such that a majority of undoped epitaxial layers 152 remains covered by insulator layers 154 after forming breaks 155C. In some embodiments, parameters of the etching process (e.g., etchant thereof) are configured to selectively remove insulator layers 154 with negligible (to no) removal of semiconductor layers 120, dummy gates 130 (e.g., hard masks thereof), gate spacers 132, inner spacers 145, undoped epitaxial layers 152, substrate isolation structures 125, or combinations thereof. In some embodiments, the etching process uses a nitrogen-based etchant including nitrogen (N₂), ammonia (NH₃), other nitrogen-containing etchant, or combinations thereof. In some embodiments, the etching process uses an etchant that includes hydrogen and nitrogen, such as an N₂/H₂ etchant. In some embodiments, the etching process implements an etch mask to achieve targeted removal of middle portions of insulator layers 154. In some embodiments, the etch mask is formed by depositing an etch mask layer(s) (e.g., one or more materials resistant to an etchant for removing insulator layers 154) and performing a lithography process to pattern the etch mask layer(s), such that the etch mask layer(s) has openings therein that expose centers of insulator layers 154 and the etch mask layer(s) covers the gate structures (e.g., top surfaces thereof) and edges/ends of insulator layers 154 (which are to remain over undoped epitaxial layers 152 and provide bottom source/drain insulation). The etch mask layer(s) may protect the gate structures and edges/ends of insulator layers 154 while the etching process removes the exposed centers of insulator layers 154. In some embodiments, the etch mask layer(s) may cover and/or protect sidewalls of semiconductor layers 120 and/or sidewalls of inner spacers 145 during the etching process.

Referring to 4E, epitaxial layers 156 and epitaxial layers 158 are formed over semiconductor layers 120, undoped epitaxial layers 152, and insulator layers 154, such as described herein. Because breaks 155C, instead of breaks 155E, are formed in insulator layers 154, bottom epitaxial portions of epitaxial layers 156 may be formed directly on and/or physically contact exposed centers 152C of undoped epitaxial layers 152. In such embodiments, the bottom epitaxial portions are disposed between and/or physically contact edges/ends of insulator layers 154, the bottom epitaxial portions may not extend over and/or physically contact inner spacers 145, epitaxial layers 158 are disposed between and/or physically contact edges/ends of insulator layers 154, and epitaxial layers 158 are separated from bottommost inner spacers 145 by insulator layers 154. Further, because undoped epitaxial layers 152 fill bottom portions of source/drain recesses 140, epitaxial layers 156 and epitaxial layers 158 are disposed above, but not below, top surfaces of mesas 105P′ in device 200 (i.e., epitaxial layers 156 and/or epitaxial layers 158 may not extend below top surfaces of mesas 105P′). Referring to FIG. 4F, device 200 may be processed further as described above with reference to FIG. 2K.

The present disclosure further contemplates embodiments where undoped epitaxial layers 152 may underfill (i.e., partially fill) bottom portions of source/drain recesses 140, yet still have flat top surfaces 152F. In such embodiments, flat top surfaces 152F of undoped epitaxial layers 152 are below top surfaces of mesas 105P′, and source/drain recesses 140 may extend a depth into mesas 105′ after forming undoped epitaxial layers 152. Accordingly, insulator layers 154 having flat top surfaces 154F, epitaxial layers 156, epitaxial layers 158, or combinations thereof may also be disposed at least partially below top surfaces of mesas 105P′.

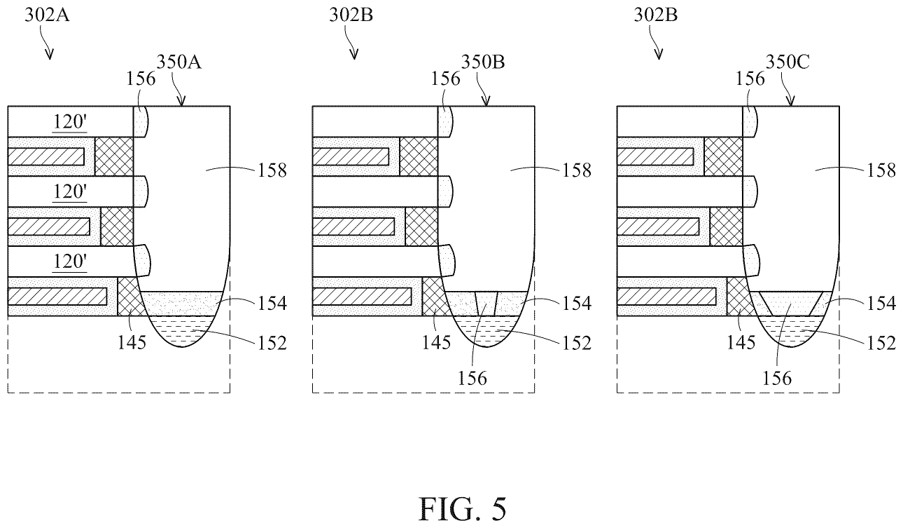

The present disclosure further contemplates configuring different device regions and/or different devices with source/drain structures having different bottom insulation. In some embodiments, bottom insulation configuration may be selected based on source/drain stress specifications for a given device. For example, FIG. 5 is a cross-sectional view of a device 300, in portion or entirety, that implements different bottom insulation configurations according to various aspects of the present disclosure. For clarity and simplicity, similar features of device 300, device 200, and device 100 are identified by the same reference numerals. Device 300 includes a transistor 302A, a transistor 302B, and a transistor 302C. Transistor 302A has source/drain structures 350A with break-free bottom insulation, transistor 302B has source/drain structures 350B with bottom insulation center breaks, and transistor 302C has source/drain structures 350C with bottom insulation center breaks that are wider/longer than the bottom insulation center breaks of source/drain structures 350C. With such bottom insulation break configurations, source/drain structures 350C may exhibit a higher stress/strain than source/drain structures 350B, which may exhibit a higher stress/strain than source/drain structures 350A. Stress/strain gains achieved by incorporating bottom insulation breaks may be balanced with performance gains achieved by incorporating bottom insulation into source/drain structures. FIG. 5 has been simplified for the sake of clarity to better understand the inventive concepts of the present disclosure. Additional features can be added in device 300, and some of the features described can be replaced, modified, or eliminated in other embodiments of device 300.

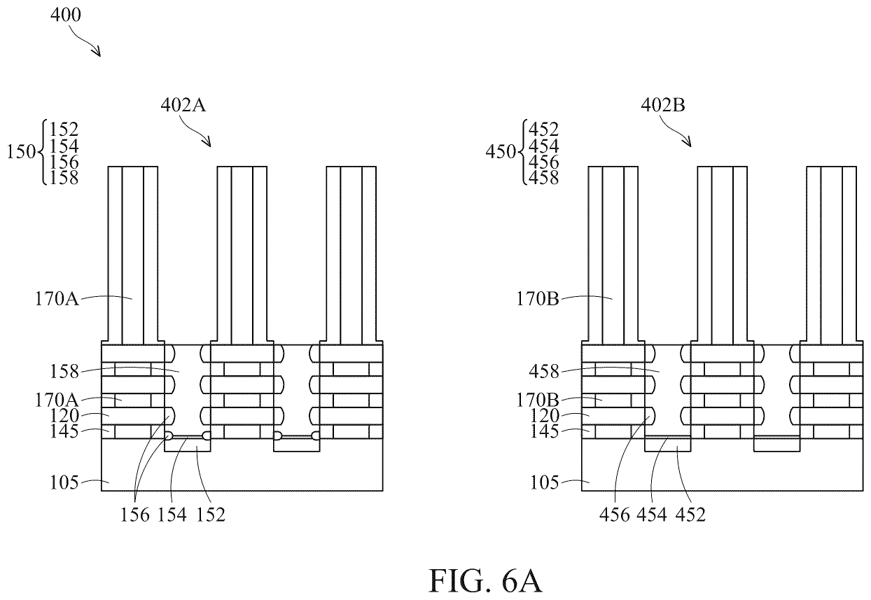

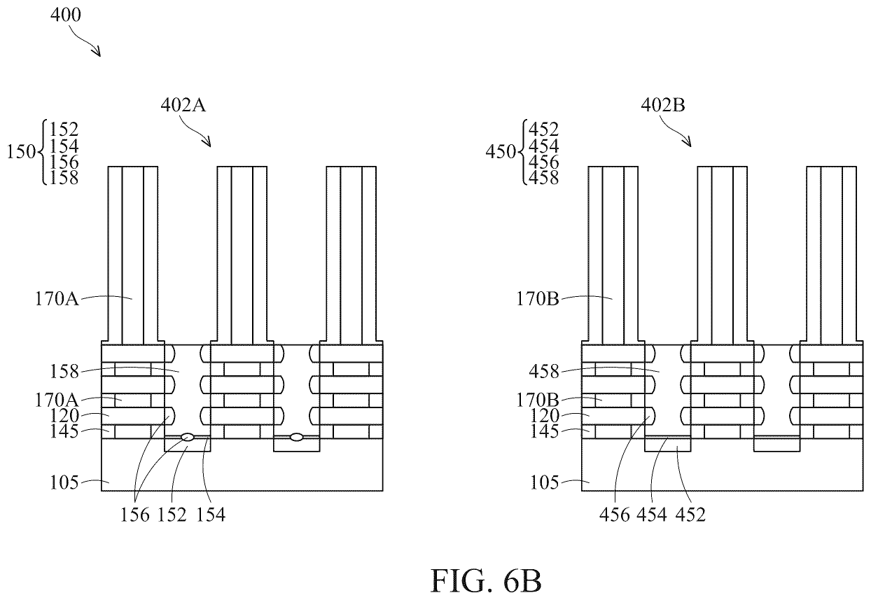

In some embodiments, bottom insulation configuration may be selected based on device type. For example, since performance of p-type transistors may be more negatively impacted by source/drain strain loss than performance of n-type transistors, p-type transistors may be configured with source/drain structures having bottom insulation with breaks, while n-type transistors may be configured with source/drain structures having break-free bottom insulation. FIG. 6A and FIG. 6B are cross-sectional views of a device 400, in portion or entirety, that implements different bottom insulation configurations according to various aspects of the present disclosure. For clarity and simplicity, similar features of device 400, device 300, device 200, and device 100 are identified by the same reference numerals. Device 400 includes a p-type transistor 402A and an n-type transistor 402B. In FIG. 6A, p-type transistor 402A is configured similar to device 100, and p-type transistor 402A has source/drain structures 150 with bottom insulation edge breaks (i.e., insulator layers 154 having breaks 155E therein, which are filled by epitaxial layers 156 and/or epitaxial layers 158). In FIG. 6B, p-type transistor 402A is configured similar to device 200, and p-type transistor 402A has source/drain structures 150 with bottom insulation center breaks (i.e., insulator layers 154 having breaks 155C therein, which are filled by epitaxial layers 156 and/or epitaxial layers 158). In both FIG. 6A and FIG. 6B, n-type transistor 402B has source/drain structures 450 with break-free bottom insulation. For example, source/drain structures 450 may include undoped epitaxial layers 452, insulator layers 454, epitaxial layers 456, and epitaxial layers 458, which may be similar to undoped epitaxial layers 152, insulator layers 154, epitaxial layers 156, and epitaxial layers 158, respectively. In contrast to insulator layers 154, insulator layers 454 do not include breaks. Accordingly, insulator layers 454 separate epitaxial layers 458 from undoped epitaxial layers 452 and epitaxial layers 456 do not include bottom epitaxial portions disposed on and/or physically contacting undoped epitaxial layers 452. In some embodiments, epitaxial layers 156 and epitaxial layers 158 include silicon germanium with different p-type dopant concentrations and/or different germanium concentrations, and epitaxial layers 456 and epitaxial layers 458 include silicon with different n-type dopant concentrations. FIG. 6A and FIG. 6B have been simplified for the sake of clarity to better understand the inventive concepts of the present disclosure. Additional features can be added in device 400, and some of the features described can be replaced, modified, or eliminated in other embodiments of device 400.

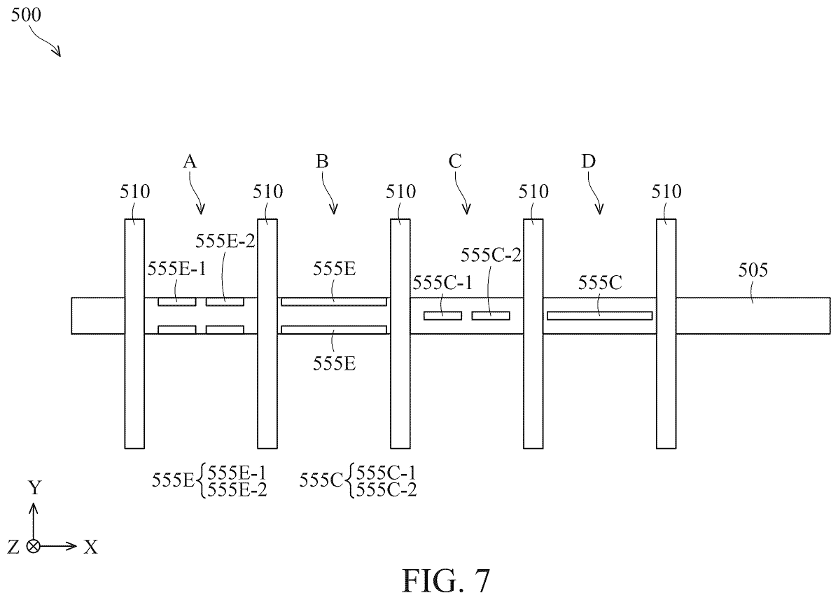

In some embodiments, bottom insulation configuration may be selected based on device region, device type, source/drain region, source/drain type, or combinations thereof. For example, FIG. 7 is a top view of a device 500, in portion or entirety, that implements different bottom insulation configurations in different source/drain regions according to various aspects of the present disclosure. For clarity and simplicity, similar features of device 500, device 400, device 300, device 200, and device 100 are identified by the same reference numerals. FIG. 7 has been simplified for the sake of clarity to better understand the inventive concepts of the present disclosure. Additional features can be added in device 500, and some of the features described can be replaced, modified, or eliminated in other embodiments of device 500.

Device 500 includes an active region 505 and gate lines 510. Active region 505 extends lengthwise along a first direction (e.g., x-direction), and gate lines 510 are oriented substantially parallel to one another and extend lengthwise along a second direction (e.g., y-direction) different than the first direction. Active region 505 (also referred to as OD regions) includes channel regions (e.g., channel layers 120′) and source/drain regions (e.g., source/drain structures 150, and each channel region may be disposed between respective source/drain regions. Gate lines 510 are disposed over respective channel regions of active region 505 and are further disposed between respective source/drain regions of active region 505. Gate lines 510 may wrap and/or surround semiconductor layers that form channel regions of active region 505, and the semiconductor layers may extend along the first direction between the source/drain regions. Gate line 510 may engage the semiconductor layers, such that current can flow between respective source/drain regions during operation. In some embodiments, a transistor is formed from one of gate lines 510 and active region 505. Isolation features may isolate active region 505 from other active regions. Gate lines 510 may each include a gate stack (e.g., gate stack 170A and/or gate stack 170B) and gate spacers (e.g., gate spacers 132).

In FIG. 7, device 500 includes a source/drain region A, a source/drain region B, a source/drain region C, and a source/drain region D, which are depicted after forming undoped epitaxial layers 152 and insulator layers 154, but before forming doped semiconductor layers (e.g., epitaxial layers 156 and/or epitaxial layers 158). Source/drain regions A-D have different bottom insulation break configurations. For example, insulator layers 154 in source/drain region A and source/drain region B have edge breaks 555E that extend lengthwise along the first direction, and insulator layers 154 in source/drain region C and source/drain region D have center breaks 555C that extend lengthwise along the first direction. Edge breaks 555E and center breaks 555C may be configured as continuous or discontinuous structures along the first direction. For example, in source/drain region B and source/drain region D, edge breaks 555E and center break 555C, respectively, have strip-like structures and extend continuously along the first direction. In contrast, in source/drain region A, edge breaks 555E have segmented structures (e.g., each of which may include an edge break segment 555E-1 and an edge break segment 555E-2), and in source/drain region C, center break 555C has a segmented structure (e.g., including a center break segment 555C-1 and a center break segment 555C-2). The present disclosure contemplates various bottom insulation break configurations.

Device 100, device 200, device 300, device 400, device 500, or combinations thereof may be included in a microprocessor, a memory, and/or other IC device. In some embodiments, device 100, device 200, device 300, device 400, device 500, or combinations thereof is a portion of an IC chip, an SoC, or portion thereof, that includes various passive and active microelectronic devices, such as resistors, capacitors, inductors, diodes, PFETs, NFETs, MOSFETs, CMOS transistors, BJTs, LDMOS transistors, high voltage transistors, high frequency transistors, other suitable components, or combinations thereof.

Epitaxial source/drain structures for enhancing performance of multigate devices, such as fin-like field-effect transistors (FETs) or gate-all-around (GAA) FETs, and methods of fabricating the epitaxial source/drain structures, are disclosed herein. The present disclosure provides for many different embodiments. An exemplary semiconductor structure includes a channel layer disposed over a substrate and a source/drain adjacent to the channel layer. The source/drain includes a base semiconductor layer having a first composition, an insulator layer disposed on the base semiconductor layer, a first semiconductor layer having a second composition, and a second semiconductor layer having a third composition. The third composition, the second composition, and the first composition are different. The base semiconductor layer is disposed in the substrate, and the insulator layer includes at least one break therein that exposes a portion of the base semiconductor layer. The first semiconductor layer is disposed on the channel layer and the exposed portion of the base semiconductor layer, and the second semiconductor layer is disposed on the insulator layer and the first semiconductor layer. In some embodiments, the exposed portion of the base layer is a first edge of the base semiconductor layer and a second edge of the base semiconductor layer, and the insulator layer covers a center of the base semiconductor layer that extends from the first edge to the second edge. In some embodiments, the exposed portion of the base semiconductor layer is a center of the base semiconductor layer that extends from a first edge of the base semiconductor layer and a second edge of the base semiconductor layer, and the insulator layer covers the first edge and the second edge of the base semiconductor layer. In some embodiments, the insulator layer includes metal and oxygen, nitrogen, carbon, or combinations thereof. In some embodiments, the insulator layer includes silicon and oxygen, nitrogen, carbon, or combinations thereof.

In some embodiments, the base semiconductor layer includes an undoped semiconductor material, the first semiconductor layer includes a first doped semiconductor material, and the second semiconductor layer includes a second doped semiconductor material. In some embodiments, the first doped semiconductor material and the second doped semiconductor material each include silicon and germanium, and a first germanium concentration in the first doped semiconductor material is less a second germanium concentration in the second doped semiconductor material. In some embodiments, the base semiconductor layer and the insulator layer are disposed below the channel layer.

An exemplary device structure includes a source/drain structure. The source/drain structure includes an undoped epitaxial layer disposed in a semiconductor mesa, an insulator layer disposed on a top surface of the undoped epitaxial layer, and a doped epitaxial layer disposed on the insulator layer and the top surface of the undoped epitaxial layer. The insulator layer covers a first portion of the top surface of the undoped epitaxial layer, and the doped epitaxial layer covers a second portion of the top surface of the undoped epitaxial layer. In some embodiments, the top surface is recessed. In some embodiments, the top surface is flat. In some embodiments, the first portion is a center portion of the top surface, and the second portion is edge portions of the top surface. In some embodiments, the first portion is edge portions of the top surface, and the second portion is a center portion of the top surface. In some embodiments, the insulator layer is disposed at least partially above a top surface of the semiconductor mesa. forming a doped semiconductor layer in the source/drain recess over exposed undoped semiconductor layer and the insulator layer. the doped epitaxial layer includes a first doped epitaxial layer and a second doped epitaxial layer. The first doped epitaxial layer may be between the second doped epitaxial layer and the second portion of the top surface of the undoped epitaxial layer.

An exemplary method includes forming a source/drain recess, forming an undoped semiconductor layer in the source/drain recess, forming an insulator layer in the source/drain recess over the undoped semiconductor layer, forming a break in the insulator layer that exposes the undoped semiconductor layer, and forming a doped semiconductor layer in the source/drain recess over the exposed undoped semiconductor layer and the insulator layer. The undoped semiconductor layer partially fills the source/drain recess, and the insulator layer partially fills the source/drain recess. In some embodiments, forming the break in the insulator layer includes forming edge breaks that expose edges of the undoped semiconductor layer. In some embodiments, forming the break in the insulator layer includes forming a center break that exposes a center of the undoped semiconductor layer. In some embodiments, forming the undoped semiconductor layer includes providing the undoped semiconductor layer with a recessed top surface. In some embodiments, forming the undoped semiconductor layer includes providing the undoped semiconductor layer with a flat top surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a channel layer disposed over a substrate;
a source/drain adjacent to the channel layer, wherein the source/drain includes:
a base semiconductor layer having a first composition, wherein the base semiconductor layer is disposed in the substrate,
an insulator layer disposed on the base semiconductor layer, wherein the insulator layer includes at least one break therein that exposes a portion of the base semiconductor layer,
a first semiconductor layer having a second composition, wherein the first semiconductor layer is disposed on the channel layer and the exposed portion of the base semiconductor layer, and
a second semiconductor layer having a third composition, wherein the second semiconductor layer is disposed on the insulator layer and the first semiconductor layer, and further wherein the third composition, the second composition, and the first composition are different.

2. The semiconductor structure of claim 1, wherein the exposed portion of the base layer is a first edge of the base semiconductor layer and a second edge of the base semiconductor layer, wherein the insulator layer covers a center of the base semiconductor layer that extends from the first edge to the second edge.

3. The semiconductor structure of claim 1, wherein the exposed portion of the base semiconductor layer is a center of the base semiconductor layer that extends from a first edge of the base semiconductor layer and a second edge of the base semiconductor layer, wherein the insulator layer covers the first edge and the second edge of the base semiconductor layer.

4. The semiconductor structure of claim 1, wherein:
the base semiconductor layer includes an undoped semiconductor material;
the first semiconductor layer includes a first doped semiconductor material; and
the second semiconductor layer includes a second doped semiconductor material.

5. The semiconductor structure of claim 4, wherein:
the first doped semiconductor material and the second doped semiconductor material each include silicon and germanium; and
a first germanium concentration in the first doped semiconductor material is less a second germanium concentration in the second doped semiconductor material.

6. The semiconductor structure of claim 1, wherein the insulator layer includes metal and oxygen, nitrogen, carbon, or combinations thereof.

7. The semiconductor structure of claim 1, wherein the insulator layer includes silicon and oxygen, nitrogen, carbon, or combinations thereof.

8. The semiconductor structure of claim 1, wherein the base semiconductor layer and the insulator layer are disposed below the channel layer.

9. A device structure comprising:
a source/drain structure that includes:
an undoped epitaxial layer disposed in a semiconductor mesa;
an insulator layer disposed on a top surface of the undoped epitaxial layer, wherein the insulator layer covers a first portion of the top surface of the undoped epitaxial layer; and
a doped epitaxial layer disposed on the insulator layer and the top surface of the undoped epitaxial layer, wherein the doped epitaxial layer covers a second portion of the top surface of the undoped epitaxial layer.

10. The device structure of claim 9, wherein the top surface is recessed.

11. The device structure of claim 9, wherein the top surface is flat.

12. The device structure of claim 9, wherein the first portion is a center portion of the top surface, and the second portion is edge portions of the top surface.

13. The device structure of claim 9, wherein the first portion is edge portions of the top surface, and the second portion is a center portion of the top surface.

14. The device structure of claim 9, wherein the insulator layer is disposed at least partially above a top surface of the semiconductor mesa.

15. The device structure of claim 9, wherein the doped epitaxial layer includes a first doped epitaxial layer and a second doped epitaxial layer, wherein the first doped epitaxial layer is disposed between the second doped epitaxial layer and the second portion of the top surface of the undoped epitaxial layer.

16. A method comprising:
forming a source/drain recess;
forming an undoped semiconductor layer in the source/drain recess, wherein the undoped semiconductor layer partially fills the source/drain recess;
forming an insulator layer in the source/drain recess over the undoped semiconductor layer, wherein the insulator layer partially fills the source/drain recess;
forming a break in the insulator layer that exposes the undoped semiconductor layer; and
forming a doped semiconductor layer in the source/drain recess over the exposed undoped semiconductor layer and the insulator layer.

17. The method of claim 16, wherein the forming the break in the insulator layer includes forming edge breaks that expose edges of the undoped semiconductor layer.

18. The method of claim 16, wherein the forming the break in the insulator layer includes forming a center break that exposes a center of the undoped semiconductor layer.

19. The method of claim 16, wherein the forming the undoped semiconductor layer includes providing the undoped semiconductor layer with a recessed top surface.

20. The method of claim 16, wherein the forming the undoped semiconductor layer includes providing the undoped semiconductor layer with a flat top surface.
